(19) United States
(12) Patent Application Publication
(10) Pub. No.: US 2015/0159267 A1
(43) Pub. Date: Jun. 11, 2015

(54) MASK UNIT AND DEPOSITION DEVICE

(71) Applicant: Sharp Kabushiki Kaisha, Osaka (JP)

(72) Inventors: Takashi Ochi, Osaka (JP); Shinichi Kawato, Osaka (JP); Tomofumi Osaki, Osaka (JP); Manabu Niboshi, Osaka (JP); Tomohiro Kosaka, Osaka (JP); Yuto Tsukamoto, Osaka (JP); Katsuhiro Kikuchi, Osaka (JP)

(21) Appl. No.: 14/412,425

(22) PCT Filed: Apr. 15, 2013
(86) PCT No.: PCT/JP2013/061201

§ 371 Date: Dec. 31, 2014

(30) Foreign Application Priority Data
Jul. 9, 2012 (JP) 2012-154106

(51) Int. Cl. C23C 16/04; C23C 16/44

(52) U.S. Cl. CPC C23C 16/042; C23C 16/44

(57) ABSTRACT

A mask unit is arranged such that at any location along an X direction with respect to openings (S) of a vapor deposition mask, the length of that portion of openings S which is uncovered by a beam portion totals a constant length along a Y direction in a plan view and that the beam portion has a part in contact with the vapor deposition mask which part does not bridge an opening of a frame portion along the Y direction but extends to cross the Y direction continuously or intermittently.

### TECHNICAL FIELD

The present invention relates to (i) a mask unit including a vapor deposition mask and a vapor deposition mask holding member holding the vapor deposition mask and (ii) a vapor deposition device including the mask unit.

### BACKGROUND ART

Recent years have witnessed practical use of flat-panel displays in various products and fields. This has led to a demand for a flat-panel display that has a larger size, that achieves higher image quality, and that consumes less power.

Under such circumstances, great attention has been drawn to an organic EL display device that (i) includes an organic electroluminescent (hereinafter abbreviated to “EL”) element which uses electroluminescence of an organic material and that (ii) is an all-solid-state flat-panel display which is excellent in, for example, low-voltage driving, high-speed response, and self-emitting.

An organic EL display device includes, for example, (i) a substrate made up of members such as a glass substrate and TFTs (thin film transistors) provided for the glass substrate and (ii) organic EL elements provided on the substrate and connected to the TFTs.

An organic EL element is a light-emitting element capable of high-luminance light emission based on low-voltage direct-current driving, and includes in its structure a first electrode, an organic EL layer, and a second electrode stacked on top of one another in that order, the first electrode being connected to a TFT. The organic EL layer between the first electrode and the second electrode is an organic layer including a stack of layers such as a hole injection layer, a hole transfer layer, an electron blocking layer, a luminous layer, a hole blocking layer, an electron transfer layer, and an electron injection layer.

A full-color organic EL display device typically includes organic EL elements of red (R), green (G), and blue (B) as sub-pixels aligned on a substrate. The full-color organic EL display device carries out an image display by, with use of TFTs, selectively causing the organic EL elements to each emit light with a desired luminance.

Such an organic EL display device includes a light-emitting section having organic EL elements that are typically formed through vapor deposition of a stack of organic films. Production of an organic EL display device involves forming, for individual organic EL elements serving as light-emitting elements, at least a predetermined pattern of a luminous layer made of organic light-emitting materials that emit the respective colors.

Such a predetermined pattern can be formed through vapor deposition of a stack of organic films by, for example, not only a vapor deposition method involving use of a vapor deposition mask called a shadow mask, but also another method such as an inkjet method and a laser transfer method. The vacuum vapor deposition method involving the use of a vapor deposition mask is currently the most common among others (see, for example, Patent Literature 1).

### CITATION LIST

Patent Literature 1

Japanese Patent Application Publication, Tokukai, No. 2006-164815 A (Publication Date: 2006 Jun. 22)

### SUMMARY OF INVENTION

### Technical Problem

In the case where vapor deposition is performed with the use of a vapor deposition mask as above, a larger substrate size unfortunately requires a larger vapor deposition mask.

Such a larger vapor deposition mask has a self-weight that forces it to bend or elongate, causing warpage in the vapor deposition mask and leaving a gap between the vapor deposition mask and a film formation target substrate for vapor deposition.

FIG. 13 is a cross-sectional view of a conventional vapor deposition mask, the view indicating a problem caused by a bend in the vapor deposition mask. FIG. 13 schematically illustrates a configuration of main constituent elements inside a conventional vapor deposition device.

As illustrated in FIG. 13, vapor deposition involving use of a vapor deposition mask 301 is performed with the vapor deposition mask 301 sandwiched between a film formation target substrate 200 and a vapor deposition source 310.

Vapor deposition materials such as organic light-emitting materials are heated under high vacuum for sublimation to be emitted from the vapor deposition source 310 in the form of vapor deposition particles.

As illustrated in FIG. 13, the vapor deposition mask 301, to prevent the vapor deposition particles from adhering to a region other than a target vapor deposition region during the vapor deposition involving the use of the vapor deposition mask 301, has openings 302 corresponding to a pattern of part of the vapor deposition region, through which openings 302 the vapor deposition particles are vapor-deposited on the film formation target substrate 200 for pattern formation.

The vapor deposition materials emitted from the vapor deposition source 310 in the form of vapor deposition particles are vapor-deposited through the openings 302 of the vapor deposition mask 301 onto the film formation target substrate 200.

This causes an organic film in a desired film formation pattern to be vapor-deposited, as a vapor-deposition film, at only a desired portion of the film formation target substrate 200 which portion corresponds to the openings 302. This organic EL vapor deposition process involves vapor-depositing luminous layers separately for each color (called “selective vapor deposition”).

In the case where such a vapor deposition process involves use of a large-sized substrate as the film formation target substrate 200, such a larger film formation target substrate 200 requires a larger vapor deposition mask 301. This causes a self-weight bend in the vapor deposition mask 301 as indicated with chain double-dashed lines in FIG. 13.

The vapor deposition source 310 emits vapor deposition particles, which are then scattered radially for vapor deposition onto the film formation target substrate 200. During this process, the vapor deposition particles are scattered from the vapor deposition source 310 at angles. The vapor deposition mask 301 being bent to be mispositioned in the height direction leads to misplacement in vapor deposition in a lateral direction.

A bend in the vapor deposition mask 301, although causing no misplacement in vapor deposition at a position P1 directly above the vapor deposition source 310, causes misplacement in vapor deposition at positions P2 and P3 away from the vapor deposition source 310 as indicated with chain double-dashed lines in FIG. 13.

During, for example, a large-scale organic EL vapor deposition process based on RGB selective vapor deposition, a bend as discussed above in the vapor deposition mask 301 decreases the positional accuracy in vapor deposition and prevents a pattern from being formed with high positional accuracy. This results in misplacement in vapor deposition or color mixture, making it difficult to achieve high resolution.

This problem is more significant in the case where the vapor deposition mask 301 is equivalent in size to the film formation target substrate 200.

FIG. 14 is a plan view of a mask unit 300 including a conventional vapor deposition mask 301 and a conventional vapor deposition mask holding member 303, the view schematically illustrating a configuration of the mask unit 300. FIG. 14 omits openings 302 of the vapor deposition mask 301.

As illustrated in FIG. 14, the mask unit 300 includes, behind the vapor deposition mask 301, a vapor deposition mask holding member 303 (called a mask frame or mask holder) holding the vapor deposition mask 301.

The vapor deposition mask holding member 303 of such a mask unit typically has a frame shape. The vapor deposition mask holding member 303 has an opening 304, and includes a frame portion 305 provided to surround the opening 304 and hold the vapor deposition mask 301.

The vapor deposition mask 301 has a peripheral portion so welded to the frame portion 305 of the vapor deposition mask holding member 303 with use of laser light or the like that the openings 302 are inside the region of the opening 304 of the vapor deposition mask holding member 303. The vapor deposition mask 301 is thus fixed to the vapor deposition mask holding member 303 (see, for example, Patent Literature 1).

Conventional techniques therefore involve welding the vapor deposition mask 301 to the vapor deposition mask holding member 303 with the vapor deposition mask 301 under sufficient tension in advance to prevent the vapor deposition mask 301 from bending after the welding.

Such a vapor deposition mask 301 welded under tension strongly pulls the frame portion 305 of the vapor deposition mask holding member 303 toward the center of the vapor deposition mask 301 as indicated with chain double-dashed lines in FIG. 14. The conventional vapor deposition mask holding member 303 is thus problematic in that deformation easily occurs at side portions of the frame portion 305, in particular, at the long-side portions as illustrated in FIG. 14.

Patent Literature 1 discloses welding, after welding the vapor deposition mask to the frame portion of the vapor deposition mask holding member, a tensioned metallic tape to a back surface of the frame portion in such a manner that the tension applied to the metallic tape is parallel in direction to the tension applied to the vapor deposition mask for prevention of warpage in a mask unit arising from warpage in the vapor deposition mask.

A larger film formation target substrate 200, however, requires a larger vapor deposition mask. It follows that merely applying tension to the vapor deposition mask will not suffice to eliminate a bend or warpage in the vapor deposition mask.

The present invention has been accomplished in view of the above problems. It is an object of the present invention to provide a mask unit and a vapor deposition device each of which allows vapor deposition to be performed through which no misplacement in vapor deposition arises from a bend in the vapor deposition mask.

### Solution to Problem

In order to solve the above problems, a mask unit of one mode of the present invention is a mask unit, including: a vapor deposition mask having an opening; and a vapor deposition mask holding member holding the vapor deposition mask, the vapor deposition mask holding member being partially in contact with a lower surface of the vapor deposition mask, the opening of the vapor deposition mask having, as viewed in a direction perpendicular to a mask surface of the vapor deposition mask, a portion uncovered by the vapor deposition mask holding member, the uncovered portion having, at any location along a first direction, a constant total opening length in a second direction orthogonal to the first direction, the vapor deposition mask holding member having, in correspondence with a portion of the vapor deposition mask which portion is other than an edge portion thereof, a contact portion extending to cross the second direction continuously or intermittently in contact with the lower surface of the vapor deposition mask, the contact portion, in correspondence with the portion of the vapor deposition mask which portion is other than the edge portion thereof, not extending continuously along the second direction from end to end of the vapor deposition mask.

Further, a vapor deposition device of one mode of the present invention includes: the mask unit; a vapor deposition source facing the vapor deposition mask of the mask unit and fixed in position relative to the vapor deposition mask; and a moving mechanism for, in a state in which the vapor deposition mask of the mask unit faces a film formation target substrate, moving a first one of (i) a combination of the mask unit and the vapor deposition source and (ii) the film formation target substrate relative to a second one thereof in a scanning direction identical to the second direction, the vapor deposition mask having a width in the second direction which width is smaller than a width of the film formation target substrate in the second direction, the vapor deposition device, while scanning the film formation target substrate along the second direction, causing the vapor deposition source to emit a vapor deposition particle through the opening of the vapor deposition mask onto the film formation target substrate for vapor deposition.

### Advantageous Effects of Invention

Either of the above arrangements can prevent deformation of the vapor deposition mask holding member such as distortion thereof without use of a thick (heavy) frame portion with high rigidity. Further, the vapor deposition mask holding member has, in correspondence with a portion of the vapor deposition mask which portion is other than an edge portion thereof, a contact portion extending to cross the second direction continuously or intermittently in contact with the lower surface of the vapor deposition mask. This can prevent a bend in the vapor deposition mask such as a self-weight bend therein.

The mask unit is further arranged such that (i) the vapor deposition mask holding member has a contact portion for contact with the vapor deposition mask, the contact portion extending to cross the second direction continuously or intermittently, and that (ii) the contact portion, in correspondence with the portion of the vapor deposition mask which portion is other than the edge portion thereof, does not extend continuously along the second direction from end to end of the vapor deposition mask. Thus, performing scan vapor deposition with the second direction as the scanning direction allows the contact portion (which is of the vapor deposition mask holding member for contact with the vapor deposition mask) to be not parallel to the scanning direction.

This indicates that even in the case where the vapor deposition mask holding member has the contact portion, using the mask unit to perform scan vapor deposition with the second direction as the scanning direction allows vapor deposition to be performed on a region in which the contact portion is present which vapor deposition is similar to vapor deposition performed on a region in which the contact portion is absent. Thus, using the above mask unit as a mask unit for scan vapor deposition allows vapor deposition to be performed through which no misplacement in vapor deposition arises from a bend in the vapor deposition mask.

The mask unit is further arranged such that the opening of the vapor deposition mask has, as viewed in a direction perpendicular to a mask surface of the vapor deposition mask, a portion uncovered by the beam portion, the uncovered portion having, at any location along a first direction, a constant total opening length in a second direction orthogonal to the first direction. This arrangement prevents the amount of vapor deposition from being uneven between individual openings adjacent to each other along the first direction, and thus allows vapor deposition to be uniformly performed even on a display region covered by the contact portion of the vapor deposition mask holding member for contact with the vapor deposition mask.

The above arrangements can thus provide a mask unit and a vapor deposition device that are advantageous in that the contact portion of the vapor deposition mask holding member for contact with the vapor deposition mask (i) does not affect vapor deposition, (ii) can prevent misplacement in vapor deposition arising from a bend in the vapor deposition mask, and (iii) allows uniform vapor deposition to be performed.

### BRIEF DESCRIPTION OF DRAWINGS

(a) to (d) of FIG. 1 are each a diagram schematically illustrating a configuration of a mask unit of Embodiment 1.

FIG. 2 is a cross-sectional view of a vapor deposition device of Embodiment 1, the view schematically illustrating a configuration of a main part of the vapor deposition device.

FIG. 3 is a bird's eye view of main constituent elements inside a vacuum chamber included in the vapor deposition device of Embodiment 1, the view illustrating how the main constituent elements are related to one another as viewed from obliquely above.

FIG. 4 is a plan view of a mask frame having a beam structure in a grid pattern, the view schematically illustrating a configuration of the mask frame.

FIG. 5 is a cross-sectional view of another mask unit of Embodiment 1, the view schematically illustrating a configuration of the mask unit.

(a) to (d) of FIG. 6 are each a diagram schematically illustrating a configuration of a mask unit of Embodiment 2.

(a) of FIG. 7 is a plan view of a vapor deposition mask holding member included in a mask unit of Embodiment 3, the view schematically illustrating a configuration of the vapor deposition mask holding member, and (b) of FIG. 7 is a plan view of a vapor deposition mask included in the mask unit illustrated in (a) of FIG. 7, the view schematically illustrating a configuration of the vapor deposition mask.

FIG. 8 is a plan view of a vapor deposition mask holding member included in a mask unit of Embodiment 4, the view schematically illustrating a configuration of the vapor deposition mask holding member, and (b) of FIG. 8 is a plan view of a vapor deposition mask included in the mask unit illustrated in (a) of FIG. 8, the view schematically illustrating a configuration of the vapor deposition mask.

FIG. 9 is a plan view of a vapor deposition mask holding member included in a mask unit of Embodiment 5, the view schematically illustrating a configuration of the vapor deposition mask holding member, and (b) of FIG. 9 is a plan view of a vapor deposition mask included in the mask unit illustrated in (a) of FIG. 9, the view schematically illustrating a configuration of the vapor deposition mask.

(a) to (c) FIG. 10 are each a diagram schematically illustrating a configuration of a mask unit of Embodiment 6.

FIG. 11 is a plan view of another vapor deposition mask for use in the mask unit illustrated in (a) of FIG. 10, the view schematically illustrating a configuration of the vapor deposition mask.

FIG. 12 is a plan view of another vapor deposition mask holding member for use in the mask unit of Embodiment 6, the view schematically illustrating a configuration of the vapor deposition mask holding member.

FIG. 13 is a cross-sectional view of a conventional vapor deposition mask, the view indicating a problem caused by a bend in the vapor deposition mask.

FIG. 14 is a plan view of a mask unit including a conventional vapor deposition mask and a conventional vapor deposition mask holding member, the view schematically illustrating a configuration of the mask unit.

### DESCRIPTION OF EMBODIMENTS

Embodiments of the present invention are described below in detail.

### Embodiment 1

An embodiment of the present invention is described below with reference to (a) and (b) of FIG. 1 through FIG. 5.

The present embodiment provides a mask unit for use in vapor deposition (scan vapor deposition) based on a scanning method, which involves use of a vapor deposition mask smaller in size than a film formation target substrate (film formation target) and which causes vapor deposition to be performed while the film formation target substrate and a combination of the mask unit and a vapor deposition source are moved relative to each other for a scan.

The description below uses (i) the term “Y direction” (Y axis direction) to refer to the scanning direction and a direction (first direction) parallel to the scanning direction and (ii) the term “X direction” (X axis direction) to refer to the direction (second direction) perpendicular to the scanning direction.

<Overall Configuration of Mask Unit 1>

(a) through (d) of FIG. 1 are each a diagram schematically illustrating a configuration of the mask unit of the present embodiment. (a) of FIG. 1 is a plan view of the mask unit of the present embodiment, the view schematically illustrating a configuration of the mask unit. (b) of FIG. 1 is a cross-sectional view of the mask unit illustrated in (a) of FIG. 1, the view being taken along line I-I in (a) of FIG. 1. (c) of FIG. 1 is a plan view of a vapor deposition mask holding member included in the mask unit illustrated in (a) of FIG. 1, the view schematically illustrating a configuration of the vapor deposition mask holding member. (d) of FIG. 1 is a plan view of a vapor deposition mask included in the mask unit illustrated in (a) of FIG. 1, the view schematically illustrating a configuration of the vapor deposition mask.

The mask unit 1 of the present embodiment includes, as illustrated in (a) through (d) of FIG. 1, (i) a vapor deposition mask 10 (called a shadow mask) and (ii) a vapor deposition mask holding member 20 (called a mask frame or mask holder) for holding the vapor deposition mask 10.

<Vapor Deposition Mask Holding Member 20>

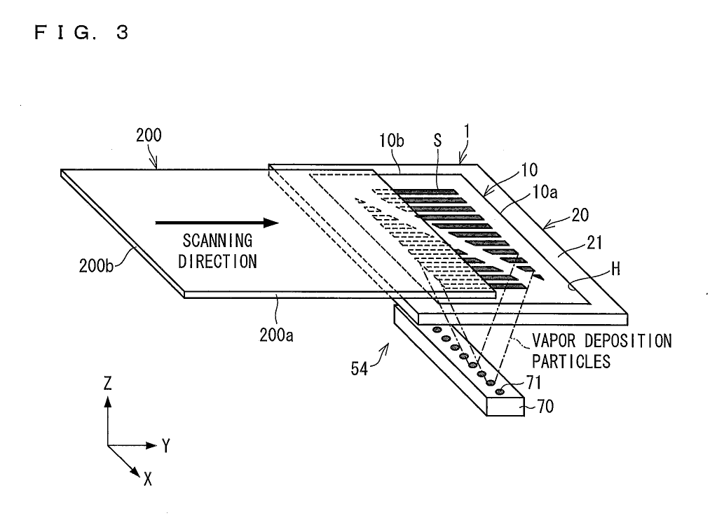

The vapor deposition mask holding member 20 of the present embodiment is in the shape of a frame that is open at a central portion as illustrated in (a) through (c) of FIG. 1 and FIG. 3.

The vapor deposition mask holding member 20 includes a frame portion 21 and a beam portion 22. The vapor deposition mask holding member 20 has an opening H (opening region) made up of two openings H1 and H2 separated from each other by the beam portion 22.

The frame portion 21 is a frame member that is quadrilateral in a plan view. The frame portion 21 holds the vapor deposition mask 10 at an outer edge thereof.

The frame portion 21, as illustrated in (a) of FIG. 1, surrounds an opening region 11 (see (d) of FIG. 1) made up of a group of openings S of the vapor deposition mask 10. The openings S of the vapor deposition mask 10 are thus located inside the region of the opening H, which is surrounded by the frame portion 21.

As illustrated in (b) of FIG. 1, the vapor deposition mask holding member 20 includes, inside the opening H (which is surrounded by the frame portion 21), a plate-shaped beam portion 22 having a thickness equal to that of the frame portion 21. The beam portion 22 has a top surface 22a that is flush with a contact surface 21a of the frame portion 21 at which contact surface 21a the frame portion 21 is in contact with the vapor deposition mask 10.

The top surface 22a of the beam portion 22 is thus in contact with a lower surface 10c of the vapor deposition mask 10. The vapor deposition mask holding member 20 supports the vapor deposition mask 10 at the frame portion 21 and the beam portion 22.

The beam portion 22, as illustrated in (a) of FIG. 1, extends on a diagonal of the frame portion 21 in such a manner as to obliquely separate the opening H (which is surrounded by the frame portion 21) into two. The beam portion 22 has a uniform width in a plan view.

The opening H (which is surrounded by the frame portion 21) is thus separated by the beam portion 22 into the openings H1 and H2. The openings H1 and H2 combine to total a constant opening length along the Y direction at any location along the X direction in a plan view. In other words, the openings H1 and H2 combine to total a constant opening length on any straight line extending along the Y direction in a plan view.

<Vapor Deposition Mask 10>

The vapor deposition mask 10 has a plurality of openings S (through holes) that allow vapor deposition particles to pass through during vapor deposition. The openings S correspond to a pattern of part of a target vapor deposition region of the film formation target substrate to prevent vapor deposition particles from adhering to a region other than the vapor deposition region.

Vapor deposition materials emitted from the vapor deposition source in the form of vapor deposition particles are vapor-deposited through the opening H (namely, the openings H1 and H2) of the vapor deposition mask holding member 20 and the openings S of the vapor deposition mask 10 onto the film formation target substrate.

This causes a vapor deposition film in a predetermined film formation pattern to be vapor-deposited at only a predetermined portion of the film formation target substrate which portion corresponds to the openings S. In the case where the vapor deposition materials are of luminous layers for an organic EL display device, the organic EL vapor deposition process performs vapor deposition of the luminous layers separately for each color.

The openings S of the vapor deposition mask 10 are, as illustrated in (a) and (d) of FIG. 1, each in the shape of a slit extending along the Y direction and arranged along the X direction to form a pattern of stripes.

The beam portion 22 and the openings S are so shaped that at any location along the X direction, the respective lengths of (i) that portion of an opening S which overlaps with the opening H1 and (ii) that portion of an opening S which overlaps the opening H2 combine to total a constant opening length in a plan view.

The present embodiment is arranged as illustrated in (a) and (d) of FIG. 1 such that the openings S are formed in respective portions of the vapor deposition mask 10 which portions do not coincide with the beam portion 22, specifically, the openings S extend, in a plan view, along the Y direction continuously or intermittently in such a pattern as to avoid the beam portion 22.

The present embodiment is thus arranged such that the openings S themselves of the vapor deposition mask 10 are so shaped that at any location along the X direction, the total opening length of openings S along the Y direction is constant in a plan view.

In the case where, for instance, the vapor deposition mask 10 has N openings S (where N is an integer of 3 or greater) arranged along the X direction as illustrated in (a) of FIG. 1, the openings S satisfy d1=d2+d3=d4, where in (a) of FIG. 1, (i) the leftmost opening S is termed opening S1, (ii) the rightmost opening S is termed opening SN, (iii) any opening S between the openings S1 and SN is termed opening SM (where M is an integer of 1<M<N), (iv) d1 represents the opening distance of that portion of the opening S1 which overlaps with the opening H1, (v) d2 represents the opening distance of that portion of the opening SM which overlaps with the opening H1, (vi) d3 represents the opening distance of that portion of the opening SM which overlaps with the opening H2, and (vii) d4 represents the opening distance of that portion of the opening SN which overlaps with the opening H2.

The vapor deposition mask 10 and the vapor deposition mask holding member 20 can each be made of a heat-resisting material similar to those which have been commonly used such as stainless steel.

The vapor deposition mask 10 can be fixed to the vapor deposition mask holding member 20 through any of various publicly known fixing methods such as welding, bonding, and screwing.

At least one of the vapor deposition mask 10 and the vapor deposition mask holding member 20 is provided with alignment markers (not shown) for alignment of the film formation target substrate and the vapor deposition mask 10 with each other. These alignment markers extend along the scanning direction of the film formation target substrate (substrate scanning direction).

The film formation target substrate is also provided with alignment markers for alignment of the film formation target substrate and the vapor deposition mask 10 with each other. These alignment markers extend outside the vapor deposition region along the scanning direction of the film formation target substrate.

The present embodiment positions the mask unit 1 in a vapor deposition device and moves (i) a film formation target substrate and (ii) a combination of the mask unit 1 and a vapor deposition source relative to each other so that the Y direction corresponds to the scanning direction. With this arrangement, at any location along the direction perpendicular to the scanning direction, the respective lengths of (i) that portion of an opening S which overlaps with the opening H1 and (ii) that portion of an opening S which overlaps with the opening H2 combine to total a constant opening length along the scanning direction in a plan view. The above arrangement, as a result, allows vapor deposition to be performed on a region in which the beam portion 22 is present which vapor deposition is similar to vapor deposition performed on a region in which the beam portion 22 is absent.

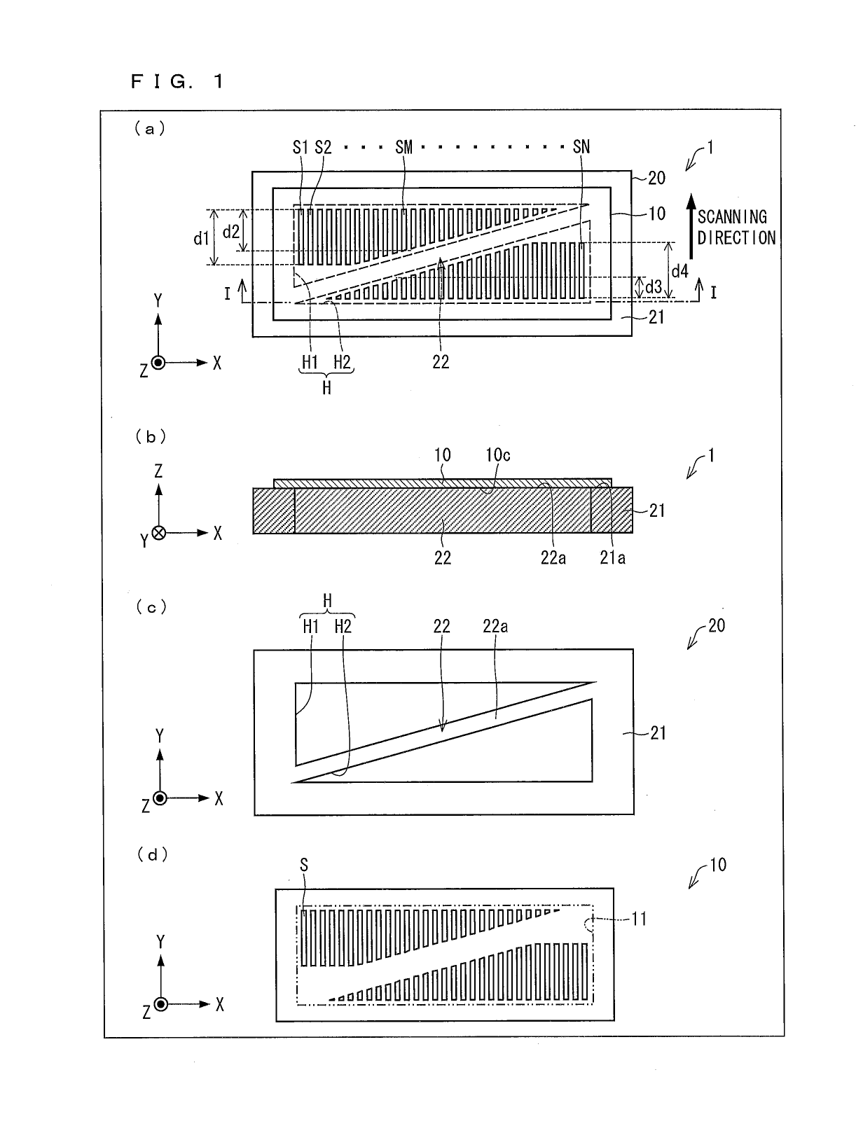

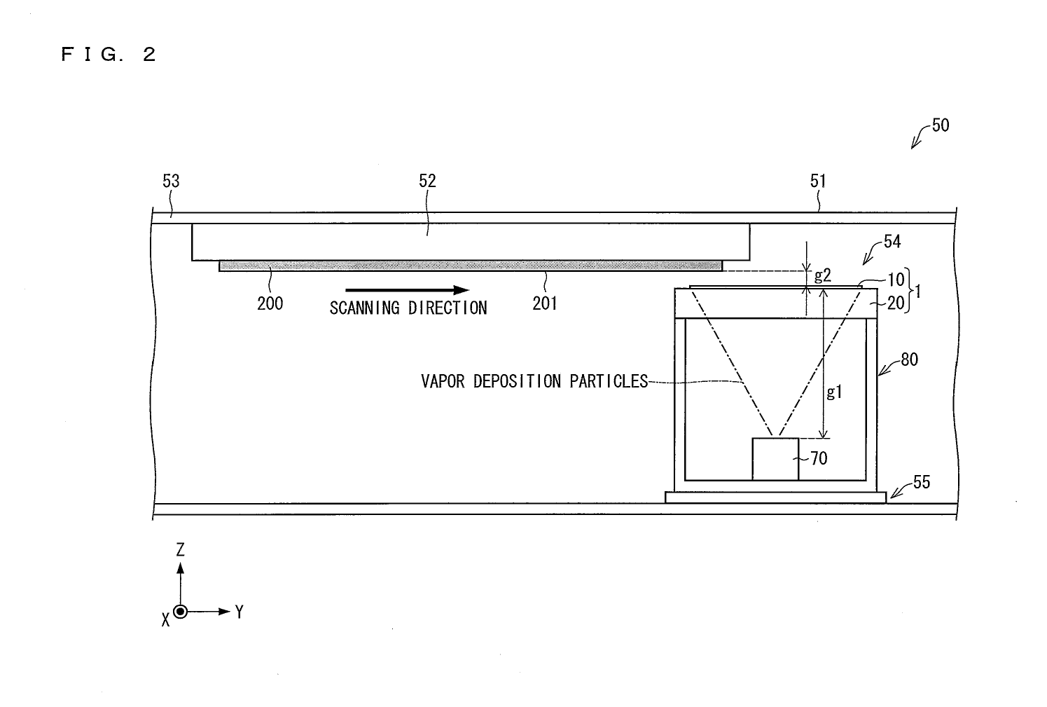

With reference to FIGS. 2 and 3, the description below deals with an example vapor deposition device including the mask unit 1.

<Overall Configuration of Vapor Deposition Device>

FIG. 2 is a cross-sectional view of a vapor deposition device of the present embodiment, the view schematically illustrating a configuration of a main part of the vapor deposition device. FIG. 2 illustrates a cross section of the vapor deposition device of the present embodiment, the cross section being taken along a direction parallel to the scanning direction.

FIG. 3 is a bird's eye view of main constituent elements inside a vacuum chamber included in the vapor deposition device of the present embodiment, the view illustrating how the main constituent elements are related to one another as viewed from obliquely above.

The vapor deposition device 50 of the present embodiment, as illustrated in FIG. 2, includes a vacuum chamber 51 (film growing chamber), a substrate holder 52 serving as a substrate holding member for holding a film formation target substrate 200, a substrate moving mechanism 53 (moving mechanism) for moving the film formation target substrate 200, a vapor deposition unit 54, a vapor deposition unit moving mechanism 55 (moving mechanism) for moving the vapor deposition unit 54, alignment observing mechanism (not shown) such as an image sensor, and a control circuit (not shown).

The vapor deposition unit 54 includes the mask unit 1 described above, a vapor deposition source 70, a mask unit fixing member 80, and a shutter (not shown).

Among the above constituent members of the vapor deposition device 50, the substrate holder 52, the substrate moving mechanism 53, the vapor deposition unit 54, and the vapor deposition unit moving mechanism 55 are contained in the vacuum chamber 51.

The vacuum chamber 51 is provided with a vacuum pump (not shown) for vacuum-pumping the vacuum chamber 51 via an exhaust port (not shown) of the vacuum chamber 51 to keep a vacuum in the vacuum chamber 51 during vapor deposition.

<Substrate Holder 52>

The substrate holder 52 holds the film formation target substrate 200 (which includes, for example, a TFT substrate) in such an orientation that a film formation target surface 201 thereof (vapor deposition target surface) faces the vapor deposition mask 10 included in the vapor deposition unit 54.

The film formation target substrate 200 and the vapor deposition mask 10 are so positioned as to face each other as separated by a fixed distance. In other words, the film formation target substrate 200 and the vapor deposition mask 10 are separated from each other by a gap having a fixed height.

The substrate holder 52 is preferably an electrostatic chuck, for example. Fixing the film formation target substrate 200 to the substrate holder 52 with use of a function of an electrostatic chuck or the like allows the film formation target substrate 200 to be held by the substrate holder 52 with no self-weight bend in the film formation target substrate 200.

<Substrate Moving Mechanism 53 and Vapor Deposition Unit Moving Mechanism 55>

The present embodiment uses at least one of the substrate moving mechanism 53 and the vapor deposition unit moving mechanism 55 to move (i) the film formation target substrate 200 and (ii) the vapor deposition unit 54 (that is, a combination of the mask unit 1 and the vapor deposition source 70) relative to each other for a scan along the Y direction as illustrated in FIGS. 2 and 3 to perform scan vapor deposition.

The substrate moving mechanism 53 includes a motor (not shown), and causes a motor drive control section (not shown) to drive the motor to move the film formation target substrate 200 held by the substrate holder 52.

The vapor deposition unit moving mechanism 55 includes a motor (not shown), and causes a motor drive control section (not shown) to drive the motor to move the vapor deposition unit 54 relative to the film formation target substrate 200 while keeping the respective positions of the vapor deposition mask 10 and the vapor deposition source 70 relative to each other.

The substrate moving mechanism 53 and the vapor deposition unit moving mechanism 55 each drive a motor (not shown) to correct the respective positions of the vapor deposition mask 10 and the film formation target substrate 200 with use of alignment markers (not shown) to eliminate mispositioning between the vapor deposition mask 10 and the film formation target substrate 200.

The substrate moving mechanism 53 and the vapor deposition unit moving mechanism 55 may each be, for example, a roller-type moving mechanism or a hydraulic moving mechanism.

The substrate moving mechanism 53 and the vapor deposition unit moving mechanism 55 may, for instance, each include (i) a driving section including such components as a motor (XY θ driving motor) such as a stepping motor (pulse motor), a roller, and a gear and (ii) a drive control section such as a motor drive control section, and cause the drive control section to drive the driving section to move the film formation target substrate 200 or the vapor deposition unit 54. The substrate moving mechanism 53 and the vapor deposition unit moving mechanism 55 may alternatively each include a driving section including such components as an XYZ stage, and be freely movable in any of the X direction, the Y direction, and the Z direction (Z axis direction).

The vapor deposition device 50, however, simply needs to be arranged such that at least one of the film formation target substrate 200 and the vapor deposition unit 54 is movable relative to the other. The vapor deposition device 50, in other words, simply needs to include at least one of the substrate moving mechanism 53 and the vapor deposition unit moving mechanism 55.

For instance, in the case where the film formation target substrate 200 is movable, the vapor deposition unit 54 may be fixed to an inner wall of the vacuum chamber 51. On the other hand, in the case where the vapor deposition unit moving mechanism 55 is movable, the substrate holder 52 may be fixed to an inner wall of the vacuum chamber 51.

<Vapor Deposition Source 70>

The vapor deposition source 70 is, for example, a container that contains a vapor deposition material. The vapor deposition source 70 may contain a vapor deposition material in advance or be provided with a load-lock pipe to receive a vapor deposition material from outside.

The vapor deposition source 70 is, for example, quadrilateral as illustrated in FIG. 3. The vapor deposition source 70 has a surface facing the vapor deposition mask 10, the surface having a plurality, for example, of emission holes 71 for emitting (scattering) the vapor deposition material in the form of vapor deposition particles.

The vapor deposition unit 54 is arranged such that the vapor deposition mask 10 and the vapor deposition source 70 are fixed in position relative to each other. This means that the vapor deposition mask 10 is separated from the surface of the vapor deposition source 70, the surface having the emission holes 71, by a constantly fixed gap g1.

The emission holes 71 are, as illustrated in FIG. 3, arranged along the direction in which the openings S of the vapor deposition mask 10 are arranged.

The emission holes 71 may, however, each have a pitch different from that of an individual opening S. Further, the emission holes 71 may each have a size different from that of an individual opening S.

For instance, in the case where the vapor deposition mask 10 has openings S in a pattern of stripes as illustrated in FIG. 3, the emission holes 71 may each have an opening diameter larger or smaller than the width of the short side of an individual opening S.

The vapor deposition source 70 may have the emission holes 71 in such a pattern that (i) a plurality of emission holes 71 correspond to a single opening S or (ii) a single emission hole 71 corresponds to a plurality of openings S. Further, the vapor deposition source 70 may have the emission holes 71 in such a pattern that either (i) part (at least one) of a plurality of emission holes 71 or (ii) a partial region of an individual emission hole 71 faces a non-opening region of the vapor deposition mask 10 (for example, a region between adjacent openings S).

To reduce the number of vapor deposition particles adhering to a non-opening region of the vapor deposition mask 10 and thus improve material use efficiency as much as possible, the emission holes 71 preferably face the openings S in such a manner that at least part of each emission hole 71 coincides with one or more openings S.

Further, the emission holes 71 more preferably face the openings S in such a manner as to be each positioned inside an opening S in a plan view.

In addition, to improve material use efficiency, the openings S and the emission holes 71 desirably correspond one-to-one to each other.

<Arrangement of Shutter>

The vapor deposition unit 54 may include the above-mentioned shutter (not shown) as necessary between the vapor deposition mask 10 and the vapor deposition source 70 in such a manner that the shutter is capable of being moved (inserted or removed) in response to a vapor deposition OFF signal or a vapor deposition ON signal to control reaching of vapor deposition particles to the vapor deposition mask 10.

The shutter is inserted between the vapor deposition mask 10 and the vapor deposition source 70 to close the openings S of the vapor deposition mask 10. Appropriately inserting the shutter between the vapor deposition mask 10 and the vapor deposition source 70 as such can prevent vapor deposition on a non-vapor deposition region, on which vapor deposition is not intended.

The shutter may be integrated with the vapor deposition source 70 or separate from the vapor deposition source 70.

The vapor deposition device 50 is so adjusted that vapor deposition particles from the vapor deposition source 70 are scattered below the vapor deposition mask 10. The vapor deposition device 50 may be arranged such that vapor deposition particles scattered accidentally beyond the vapor deposition mask 10 are blocked as appropriate by, for example, a deposition preventing plate (shielding plate).

<Mask Unit Fixing Member 80>

The mask unit fixing member 80 is a stand on which to place the mask unit 1 and onto which to hold and fix the mask unit 1.

The mask unit 1 is, as illustrated in FIG. 2, held by and fixed to the mask unit fixing member 80. The vapor deposition source 70 is disposed under the mask unit 1.

The mask unit fixing member 80 is not limited to any particular shape. The mask unit fixing member 80 simply needs to be capable of holding and fixing the mask unit 1 at such a position that the mask unit 1 is separated from the vapor deposition source 70 by a fixed distance.

The mask unit 1 and the vapor deposition source 70 are, for example, held integrally by the mask unit fixing member 80. The vapor deposition mask 10 of the mask unit 1 and the vapor deposition source 70 are thus fixed in position relative to each other.

This means that the vapor deposition mask 10 is separated from the surface of the vapor deposition source 70, the surface having the emission holes 71, by a gap having a fixed height (vertical distance) and that the openings S of the vapor deposition mask 10 are fixed in position relative to the emission holes 71 of the vapor deposition source 70.

In the case where (i) the vapor deposition unit 54 is fixed and (ii) the film formation substrate 200 is moved relative to the vapor deposition unit 54, the mask unit 1 and the vapor deposition source 70 simply need to be fixed in position relative to each other, and are not necessarily integrated with each other as described above.

For instance, the vapor deposition source 70 and the mask unit fixing member 80 may each be so fixed to an inner wall of the vacuum chamber 51 that the mask unit 1 and the vapor deposition source 70, specifically the vapor deposition mask 10 and the vapor deposition source 70, are fixed in position relative to each other.

Further, the vapor deposition device 50 may include, as a deposition preventing plate that doubles as a section for holding a constituent inside the vacuum chamber, such a component as a holder adjacent to the inner wall of the vacuum chamber 2 and having a shelf, on which shelf the mask unit 1 is placed. In other words, the shelf of the holder may be used as the mask unit fixing member 80.

The vapor deposition mask 10 and the vapor deposition source 70 face each other as separated from each other by a fixed distance in such a manner as to be separated from each other by a gap g1 having a fixed height.

The gap g1 may be set to any distance, and is not limited to any particular distance. To improve the efficiency in the use of vapor deposition materials, however, the gap g1 is desirably as small as possible, for example, approximately H mm.

The vapor deposition mask 10 and the film formation target substrate 200 face each other as separated from each other by a fixed distance in such a manner as to be separated from each other by a gap g2 having a fixed height.

The vapor deposition mask 10 and the film formation target substrate 200 are preferably separated from each other by a gap having a height (vertical distance) of 50 μm or larger and 1 mm or smaller, more preferably 200 to 500 μm.

The gap g2 having a height of smaller than 50 μm will increase the risk of the film formation target substrate 200 coming into contact with the vapor deposition mask 10.

The gap g2 having a height of larger than 1 mm will let vapor deposition particles having passed through the openings S of the vapor deposition mask 10 spread widely, with the result of a vapor deposition film being formed to have an excessively large pattern width. In the case where, for instance, the vapor deposition film is a red luminous layer for use in an organic EL display device, the gap g2 having a height of larger than 1 mm may undesirably let a red light-emitting material be vapor-deposited also on adjacent sub-pixels, that is, such sub-pixels as green or blue sub-pixels.

The gap g2 having a height of approximately 200 to 500 μm eliminates the risk of the film formation target substrate 200 coming into contact with the vapor deposition mask 10, and also allows a vapor deposition film to have a sufficiently small pattern width.

<Effects>

The present embodiment is arranged such that the frame portion 21 is combined with the beam portion 22 as described above. This combination can prevent deformation of the frame portion 21 such as distortion thereof without use of a thick (heavy) frame portion with high rigidity. The present embodiment is further arranged such that the beam portion 22 is inside the opening H, which is surrounded by the frame portion 21, and in contact with the vapor deposition mask 10. This can prevent a bend in the vapor deposition mask 10 such as a self-weight bend therein.

The present embodiment is arranged such that the beam portion 22 extends across a central portion of the vapor deposition mask 10, at which central portion the vapor deposition mask 10 is easily bendable. This arrangement can directly prevent a bend in the vapor deposition mask 10.

As described above, the present embodiment uses, for scan vapor deposition, a mask unit 1 having an optimal frame structure with a beam (crosspiece). This can provide a vapor deposition mask 10 free from a bend.

Conventional vapor deposition methods other than the scan vapor deposition method use a vapor deposition mask having a size substantially equal to that of a film formation target substrate to perform vapor deposition. Such conventional vapor deposition methods cannot use a mask frame having a beam structure because such a mask frame having a beam structure would prevent vapor deposition particles from being vapor-deposited on a region covered by the beam.

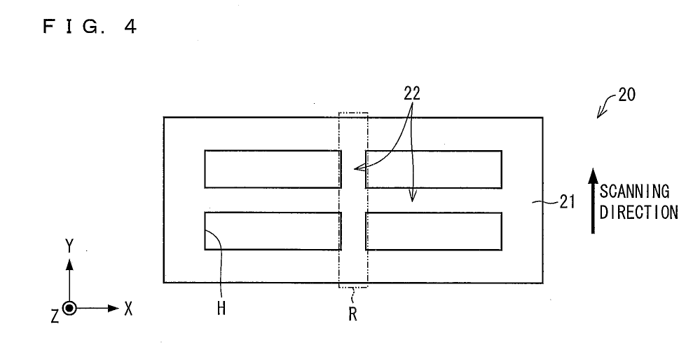

Further, if the vapor deposition mask holding member 20 has a beam portion 22 having a grid pattern and connected to the frame portion 21 as illustrated in FIG. 4, even using the scan vapor deposition method would, in that region of the film formation target substrate which overlaps with a region R of the vapor deposition mask holding member 20 in which region R that portion of the beam portion 22 which extends parallel to the scanning direction is present, prevent vapor deposition particles from passing through the vapor deposition mask 10 and thus from being vapor-deposited on that region of the film formation target substrate. The vapor deposition mask holding member 20 thus cannot have such a beam structure in correspondence with the film formation region (vapor deposition region) of the film formation target substrate.

In contrast, the present embodiment is arranged as described above to (i) include a beam portion 22 extending to cross the X direction, in which the openings S are arranged, and to (ii) perform scan vapor deposition with the Y direction, which is perpendicular to the X direction, as the scanning direction. The beam portion 22 of the present embodiment is thus not parallel to the scanning direction.

The present embodiment is arranged as described above such that (i) the beam portion 22 extends obliquely to cross the Y direction, which is identical to the scanning direction, and that (ii) the beam portion 22 does not bridge the opening H of the frame portion 21 along the Y direction.

The mask unit 1 of the present embodiment, in other words, does not have a beam portion extending parallel to the Y direction from end to end of the region surrounded by the frame portion 21.

The above arrangement allows vapor deposition to be performed similarly on a region covered by the beam portion 22 and on a region uncovered by the beam portion 22. This in turn allows vapor deposition to be performed through which no misplacement in vapor deposition arises from a bend in the vapor deposition mask 10.

Further, the present embodiment is arranged as described above such that at any location along the X direction, the respective lengths of (i) that portion of an opening S which overlaps with the opening H1 and (ii) that portion of an opening S which overlaps with the opening H2 combine to total a constant opening length in a plan view. This arrangement prevents the amount of vapor deposition from being uneven between individual openings S, that is, between openings S adjacent to each other along the X direction, and thus allows vapor deposition to be uniformly performed even on a display region covered by the beam portion 22. The present embodiment is thus advantageous in that the beam portion 22 (i) does not affect vapor deposition, (ii) can prevent misplacement in vapor deposition arising from a bend in the vapor deposition mask 10, and thereby (iii) allows uniform vapor deposition to be performed. This allows the present embodiment to provide, for example, an organic EL display device free from color mixture.

As described earlier, conventional techniques involve welding a vapor deposition mask to a vapor deposition mask holding member with the vapor deposition mask under sufficient tension in advance to prevent the vapor deposition mask from bending after the welding. The vapor deposition mask holding member is, however, easily deformed at a frame portion, which is pulled by the vapor deposition mask welded under tension. Conventional techniques thus require such a frame portion to be a thick (heavy) frame portion with high rigidity.

As described above, however, the present embodiment is arranged to include a beam portion 22 extending across a central portion of the vapor deposition mask 10, at which central portion the vapor deposition mask 10 is easily bendable, to directly prevent a bend in the vapor deposition mask 10. This arrangement allows the vapor deposition mask 10 to be under reduced tension as compared to conventional techniques. The present embodiment, in particular, includes a beam portion 22 on a diagonal of the frame portion 21. This arrangement allows the beam portion 22 to function as a cross bracing.

The above arrangement eliminates the need for a thick (heavy) frame portion with high rigidity, and allows the frame portion 21 to be thin and lightweight as compared to conventional techniques. The present embodiment thus, even with use of the beam portion 22, allows the vapor deposition mask holding member 20 to be lightweight as compared to conventional techniques.

The present embodiment uses, as an example, (i) a frame portion 21 having a length of 750 mm along the Y direction and a length of 365 mm along the X direction, the frame portion including a frame body having a width of 30 mm in a plan view and a thickness of 20 mm, and (ii) a beam portion 22 including a plate-shaped member having a width of 5 mm in a plan view and a thickness of 20 mm.

The opening H1 of the present embodiment is designed to have a distance (opening distance) of 300 mm to 0 mm along the Y direction. Specifically, in (b) of FIG. 1, the opening H1 is designed to have an opening distance of 300 mm at the leftmost end and an opening distance of 0 mm at the rightmost end, the opening H1 having a smaller opening distance toward the right side.

The opening H2 is designed to have a distance (opening distance) of 0 mm to 300 mm along the Y direction. Specifically, in (b) of FIG. 1, the opening H2 is designed to have an opening distance of 0 mm at the leftmost end and an opening distance of 300 mm at the rightmost end, the opening H2 having a larger opening distance toward the right side.

The above values are, however, mere examples. The vapor deposition mask holding member 20 is not limited by the above values, and may be designed in any manner.

<Variation>

(Thickness of Beam Portion 22)

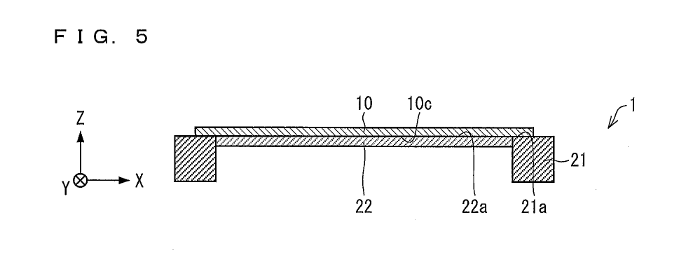

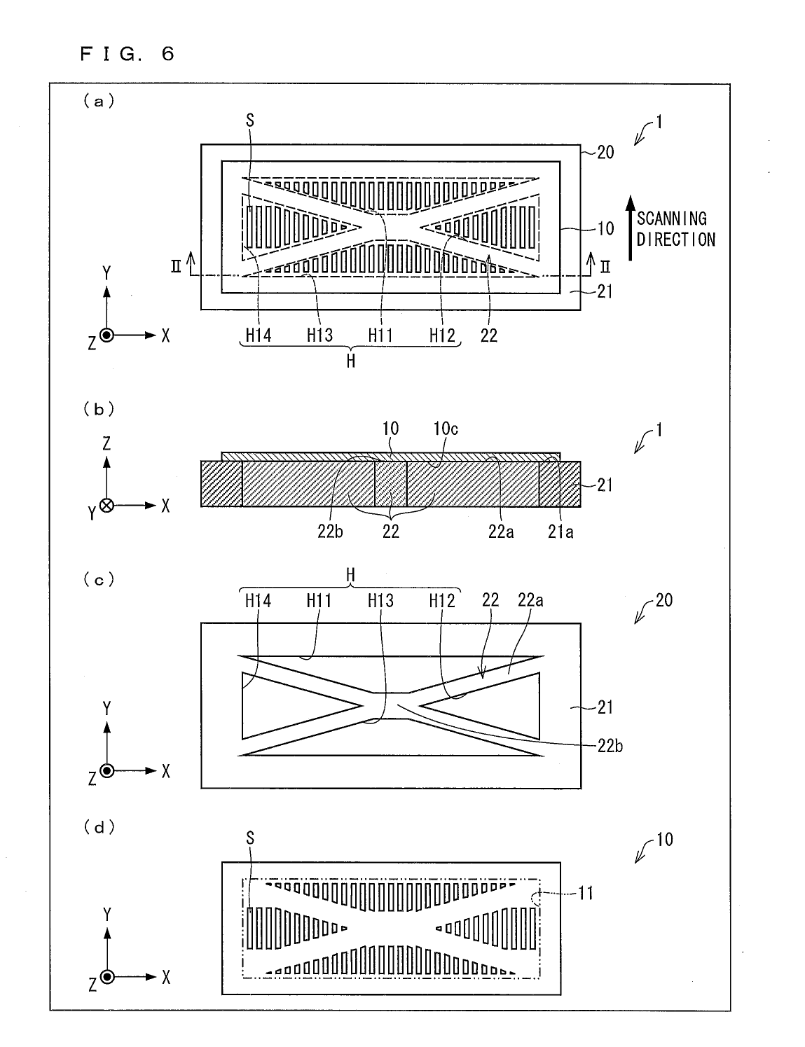

FIG. 5 is a cross-sectional view of another mask unit 1 of the present embodiment, the view schematically illustrating a configuration of the mask unit 1.

(b) of FIG. 1 illustrates an example case of a plate-shaped beam portion 22 being formed inside the opening H, which is surrounded by the frame portion 21, and having a thickness equal to that of the frame portion 21.

The mask unit 1 illustrated in FIG. 5 differs from the mask unit 1 illustrated in (a) and (b) of FIG. 1 in that the beam portion 22 has a thickness smaller than that of the frame portion 21.

In the present embodiment as well, the beam portion 22 has a top surface 22a flush with a contact surface 21a of the frame portion 21 at which contact surface 21a the frame portion 21 is in contact with the vapor deposition mask 10.

As described above, the present embodiment eliminates the need for a thick (heavy) frame portion with high rigidity.

Thus, forming a beam portion 22 thinner than the frame portion 21 disposed at the outer edge as illustrated in FIG. 5 allows the mask unit 1 of the present variation to be lighter in weight than the mask unit 1 illustrated in (a) and (b) of FIG. 1.

(Opening Shape)

(a) and (d) of FIG. 1 and FIG. 3 each illustrate an example case of a vapor deposition mask 10 having openings S each in the shape of a slit extending along the Y direction and arranged along the X direction to form a pattern of stripes.

The openings S may, however, have any shape. The openings S may, for example, each be in the shape of a slot and arranged along the X direction. Such slot-shaped openings may alternatively be arranged along the X direction and the Y direction to form a staggered pattern.

The vapor deposition mask 10 may be, for example, a fine mask having openings S corresponding one-to-one to individual pixels or an open mask that is open over the entire region having a length along the X direction which length is equal to the length of a display region of the film formation target substrate 200 along the X direction.

The mask unit 1, needless to say, produces a particularly great effect in the case where the mask unit 1 includes a vapor deposition mask 10 having a mask section (that is, a non-opening region between adjacent openings S) in a region of the vapor deposition mask 10 at which region the vapor deposition mask 10 is easily bendable, in particular a central region of the vapor deposition mask 10 at which central region the vapor deposition mask 10 is most easily bendable.

The present embodiment, in any case, simply needs to be arranged such that in the case where the vapor deposition mask 10 and the vapor deposition mask holding member 20 are combined with each other for use as the mask unit 1, the beam portion 22 inside the opening H and the openings S of the vapor deposition mask 10 are so shaped that at any location along the X direction, the length of that portion of openings S which does not coincide with the beam portion 22 (that is, which is uncovered by the beam portion 22) totals a constant length along the Y direction in a plan view.

In other words, the mask unit 1 of the present embodiment simply needs to be arranged such that at any location along the X direction (which is perpendicular to the scanning direction), the beam portion 22 inside the opening H and the openings S are so shaped in a plan view that the total opening length is constant of (i) the length of that portion of an opening S which overlaps with the opening H1 and (ii) the length of that portion of an opening S which overlaps with the opening H2, so that at any point along the X direction (which is perpendicular to the scanning direction for the opening H), the substantial total opening length is constant along the Y direction (which is identical to the scanning direction for the opening H) in a plan view.

(Size of Vapor Deposition Mask)

The mask unit 1 is so designed for downsizing thereof that the vapor deposition mask 10 has a short-axis direction (short-side direction) identical to the scanning direction as illustrated in (a) of FIG. 1 and FIG. 3, and is mounted in the vapor deposition device 50.

The present embodiment, as illustrated in FIG. 3, uses a quadrilateral vapor deposition mask 10 having (i) long sides 10a with a width larger than the width of the short sides 200b of the film formation target substrate 200 which short sides 200b are parallel to the long side 10a and (ii) short sides 10b with a width smaller than the width of the long sides 200a of the film formation target substrate 200 which long sides 200a are parallel to the short sides 10b.

The long sides 200a of the film formation target substrate 200 are, however, not limited to the above orientation with respect to the vapor deposition mask 10. It should be needless to say that the vapor deposition mask 10 and the film formation target substrate 200 may be, depending on the size of the film formation target substrate 200, so positioned that the vapor deposition mask 10 has long sides 10a parallel to the long sides 200a of the film formation target substrate 200.

The present embodiment uses, as the vapor deposition mask 10 and the vapor deposition mask holding member 20 each of which is quadrilateral in a plan view, a vapor deposition mask 10 and a vapor deposition mask holding member 20 each of which is rectangular in a plan view. It should be needless to say, however, that the present embodiment may use, as the vapor deposition mask 10 and the vapor deposition mask holding member 20, a vapor deposition mask 10 and a vapor deposition mask holding member 20 each of which is square in a plan view.

(Size of Frame Portion)

(a) and (b) of FIG. 1 illustrate an example case of a vapor deposition mask 10 being quadrilateral and a vapor deposition mask holding member 20 having a quadrilateral frame portion 21 slightly larger in length and width than the vapor deposition mask 10 in a plan view.

The frame portion 21 may, however, be equal in size to the vapor deposition mask 10 in a plan view. Further, the mask unit 1 may be arranged such that (i) the vapor deposition mask 10 has an opening region 11 surrounded by an outer edge portion larger than the frame portion 21 and that (ii) the vapor deposition mask 10 is wound around the frame portion 21 to be fixed to the vapor deposition mask holding member 20.

### Embodiment 2

The present embodiment is described below with reference to (a) through (d) of FIG. 6.

The description below mainly deals with how the present embodiment differs from Embodiment 1. Any constituent element of the present embodiment that is identical in function to a constituent element in Embodiment 1 is assigned a common reference numeral, and is not described here.

(a) through (d) of FIG. 6 are each a diagram schematically illustrating a configuration of a mask unit 1 of the present embodiment. (a) of FIG. 6 is a plan view of the mask unit 1 of the present embodiment, the view schematically illustrating a configuration of the mask unit 1. (b) of FIG. 6 is a cross-sectional view of the mask unit 1 illustrated in (a) of FIG. 6, the view being taken along line II-II in (a) of FIG. 6. (c) of FIG. 6 is a plan view of a vapor deposition mask holding member 20 included in the mask unit 1 illustrated in (a) of FIG. 6, the view schematically illustrating a configuration of the vapor deposition mask holding member 20. (d) of FIG. 6 is a plan view of a vapor deposition mask 10 included in the mask unit 1 illustrated in (a) of FIG. 6, the view schematically illustrating a configuration of the vapor deposition mask 10.

The mask unit 1 of the present embodiment is similar in configuration to the mask unit 1 of Embodiment 1 except for (i) the planar shape of a beam portion 22 (in other words, the opening shape of an opening H) of the vapor deposition mask holding member 20 and (ii) the opening shape of openings S of the vapor deposition mask 10.

<Vapor Deposition Mask Holding Member 20>

The vapor deposition mask holding member 20 of the present embodiment, as illustrated in (a) and (c) of FIG. 6, includes a beam portion 22 on the two diagonals of a quadrilateral frame portion 21. The vapor deposition mask holding member 20 of the present embodiment thus has an opening H surrounded by the frame portion 21, the opening H being separated into four openings H11 to H14 by the beam portion 22, which is in the shape of a cross that is oblique with respect to the Y direction.

As illustrated in (b) of FIG. 6, the beam portion 22 of the present embodiment, as in Embodiment 1, has a thickness equal to that of the frame portion 21, and has a top surface 22a flush with a contact surface 21a of the frame portion 21 at which contact surface 21a the frame portion 21 is in contact with the vapor deposition mask 10. With this arrangement, the vapor deposition mask holding member 20 of the present embodiment supports the vapor deposition mask 10 at the frame portion 21 and the beam portion 22, which includes beams extending to intersect with each other obliquely with respect to the Y direction.

The present embodiment is further arranged as illustrated in (a) and (c) of FIG. 6 such that in a plan view, (i) a part of the beam portion 22 which part (beam portion intersection region 22b) is at the intersection of the two diagonals and (ii) the vicinity of that part have a width along the Y direction which width is twice as large as the width of the other region of the beam portion 22 along the Y direction.

The openings H11 to H14, which are separated from one another by the beam portion 22, thus combine to total a constant opening length along the Y direction at any location along the X direction in a plan view. In other words, the openings H11 to H14 combine to total a constant opening length on any straight line extending along the Y direction in a plan view.

<Vapor Deposition Mask 10>

(a) and (d) of FIG. 6 illustrate an example case of a vapor deposition mask 10 having openings S each in the shape of a slit extending along the Y direction and arranged along the X direction to form a pattern of stripes. As mentioned in the description of Embodiment 1, the above opening shape is a mere example, and the present embodiment is not limited by the above arrangement.

The present embodiment is, as in Embodiment 1, arranged as illustrated in (a) and (d) of FIG. 6 such that the openings S are formed in respective portions of the vapor deposition mask 10 which portions do not coincide with the beam portion 22, specifically, the openings S extend, in a plan view, along the Y direction continuously or intermittently in such a pattern as to avoid the beam portion 22.

Thus, the present embodiment is, as in Embodiment 1, arranged such that (i) the openings S themselves of the vapor deposition mask 10 are so shaped that at any location along the X direction, the total opening length of openings S along the Y direction is constant in a plan view and that (ii) the length of that portion of openings S which overlaps with, among the openings H11 to H14, openings on any straight line extending along the Y direction is constant at any location along the X direction.

<Effects>

As described above, the present embodiment, as in Embodiment 1, positions the mask unit 1 in a vapor deposition device 50 and moves (i) a film formation target substrate 200 and (ii) a combination of the mask unit 1 and a vapor deposition source 70 relative to each other so that the Y direction corresponds to the scanning direction. With this arrangement, at any location along the direction perpendicular to the scanning direction, the respective lengths of those portions of openings S which overlap with the openings H11 to H14 combine to total a constant opening length along the scanning direction in a plan view. The above arrangement, as a result, allows vapor deposition to be performed on a region in which the beam portion 22 is present which vapor deposition is similar to vapor deposition performed on a region in which the beam portion 22 is absent.

The above arrangement allows vapor deposition to be performed through which no misplacement in vapor deposition arises from a bend in the vapor deposition mask 10. Further, the above arrangement prevents the amount of vapor deposition from being uneven between individual openings S, that is, between openings S adjacent to each other along the X direction, and allows vapor deposition to be uniformly performed even on a display region covered by the beam portion 22. This allows the present embodiment to provide, for example, an organic EL display device free from color mixture.

The present embodiment is, as in Embodiment 1, arranged such that the frame portion 21 is combined with the beam portion 22 as described above. This combination can prevent deformation of the frame portion 21 such as distortion thereof. The present embodiment is further arranged such that the beam portion 22 is inside the opening H, which is surrounded by the frame portion 21, and in contact with the vapor deposition mask 10. This can prevent a bend in the vapor deposition mask 10 such as a self-weight bend therein.

The present embodiment is, as in Embodiment 1, arranged such that the beam portion 22 extends across a central portion of the vapor deposition mask 10, at which central portion the vapor deposition mask 10 is easily bendable. This arrangement can directly prevent a bend in the vapor deposition mask 10.

In addition, the present embodiment is arranged such that the beam portion 22 is in the shape of a cross and has a branching portion. This arrangement allows the present embodiment to produce the effect of preventing a bend in the vapor deposition mask 10, the effect being greater than that of Embodiment 1.

With the above arrangement, the present embodiment, as in Embodiment 1, allows the vapor deposition mask 10 to be under reduced tension as compared to conventional techniques. This eliminates the need for a thick (heavy) frame portion with high rigidity, and allows the frame portion 21 to be thin and lightweight as compared to conventional techniques. The present embodiment thus, even with use of the beam portion 22, allows the vapor deposition mask holding member 20 to be lightweight as compared to conventional techniques.

(b) of FIG. 6 illustrates an example case of a plate-shaped beam portion 22 being formed inside the opening H, which is surrounded by the frame portion 21, and having a thickness equal to that of the frame portion 21.

However, the present embodiment may, as in Embodiment 1, be arranged such that the beam portion 22 has a thickness smaller than that of the frame portion 21 as illustrated in FIG. 5.

It is needless to say that the present embodiment may also be varied as in Variation of Embodiment 1.

<Variation>

The present embodiment is described with reference to FIG. 6 as an example case in which in a plan view, the beam portion intersection region 22b and its vicinity of the beam portion 22 have a width along the Y direction which width is twice as large as the width of the other region of the beam portion 22 along the Y direction. Alternatively, the present embodiment may, depending on the opening pattern of the openings S (for example, the shape and pitch thereof), be arranged such that in a plan view, only the beam portion intersection region 22b of the beam portion 22 has a width along the Y direction (in other words, the width of the beam portion intersection region 22b along the Y direction) which width is twice as large as the width of the other region of the beam portion 22 along the Y direction.

### Embodiment 3

The present embodiment is described below with reference to (a) and (b) of FIG. 7.

The description below mainly deals with how the present embodiment differs from Embodiment 2. Any constituent element of the present embodiment that is identical in function to a constituent element in Embodiment 1 is assigned a common reference numeral, and is not described here.

(a) of FIG. 7 is a plan view of a vapor deposition mask holding member 20 included in a mask unit 1 of the present embodiment, the view schematically illustrating a configuration of the vapor deposition mask holding member 20. (b) of FIG. 7 is a plan view of a vapor deposition mask 10 included in the mask unit 1 illustrated in (a) of FIG. 7, the view schematically illustrating a configuration of the vapor deposition mask 10.

The mask unit 1 of the present embodiment is similar in configuration to the mask unit 1 of Embodiment 2 except for (i) the planar shape of a beam portion 22 (in other words, the opening shape of an opening H) of the vapor deposition mask holding member 20 and (ii) the opening shape of openings S of the vapor deposition mask 10. The description below thus deals only with those shapes.

<Vapor Deposition Mask Holding Member 20>

The vapor deposition mask holding member 20 of the present embodiment, as illustrated in (a) of FIG. 7, includes a beam portion 22 on the two diagonals of a quadrilateral frame portion 21. The vapor deposition mask holding member 20 of the present embodiment thus has an opening H surrounded by the frame portion 21, the opening H being separated into four openings H21 to H24 by the beam portion 22, which is in the shape of a cross that is oblique with respect to the Y direction.

The present embodiment is arranged such that any part of the beam portion 22 has a uniform width in a plan view and that the beam portion 22 (which is inside an opening H surrounded by the frame portion 21) has a branching portion other than a beam portion intersection region 22b (which is in the shape of a cross). The total opening length along the Y direction is thus larger in correspondence with the beam portion intersection region 22b than in correspondence with the other region inside the opening H.

<Vapor Deposition Mask 10>

The present embodiment is, as described above, arranged such that the total opening length along the Y direction is larger in correspondence with the beam portion intersection region 22b than in correspondence with the other region inside the opening H. The present embodiment is thus arranged such that, at a location along the X direction at which location the beam portion intersection region 22b is present in the Y direction, the vapor deposition mask 10 has an opening length along the Y direction which opening length is smaller than in correspondence with the other region inside the opening H so that in a plan view, that portion of any of the openings S arranged along the X direction which overlaps with the opening H has a constant opening length along the Y direction.

In other words, the present embodiment simply needs to be arranged, to prevent the amount of vapor deposition from being uneven between openings S adjacent to each other along the X direction, such that at any location along the X direction (which is perpendicular to the scanning direction for the opening H), the substantial total opening length is constant along the Y direction (which is identical to the scanning direction for the opening H) in a plan view.

The present embodiment is, as described above, arranged such that the openings S are so designed that in the case where the vapor deposition mask holding member 20 and the vapor deposition mask 10 are combined with each other for use as a mask unit 1, the length of that portion of openings S which overlaps with, among the openings H21 to H24, openings on any straight line extending along the Y direction is constant at any location along the X direction in a plan view. This arrangement allows the present embodiment to produce an effect similar to that of Embodiment 2.

<Variation>

(a) and (b) of FIG. 7 illustrate an example case of a beam portion 22 partially overlapping with openings S. The present embodiment is, however, not limited to such an arrangement. For instance, the vapor deposition mask 10 may be unopened at a region of the openings S illustrated in (b) of FIG. 7 which region overlaps with the beam portion 22. The vapor deposition mask 10 may, in other words, has no opening S in a region at which the vapor deposition mask 10 overlaps with the needle portion 22. In this case as well, the present embodiment is arranged such that in the case where the vapor deposition mask holding member 20 and the vapor deposition mask 10 are combined with each other for use as a mask unit 1, the substantial opening length along the Y direction in a plan view is the same as in the case where the vapor deposition mask 10 illustrated in (b) of FIG. 7 is used. Thus, even in that case, the present embodiment can produce the same effect as the above.

### Embodiment 4

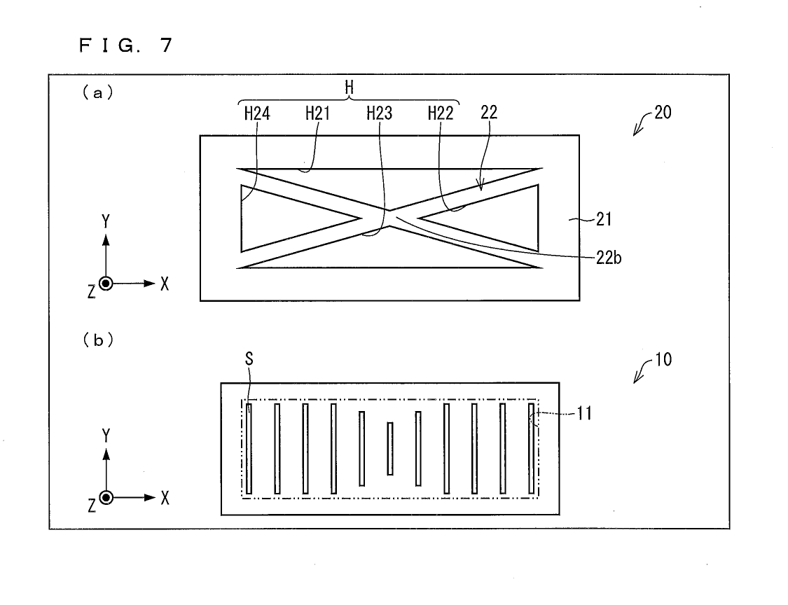

The present embodiment is described below with reference to (a) and (b) of FIG. 8.

The description below mainly deals with how the present embodiment differs from Embodiments 1 to 3. Any constituent element of the present embodiment that is identical in function to a constituent element in Embodiments 1 to 3 is assigned a common reference numeral, and is not described here.

(a) of FIG. 8 is a plan view of a vapor deposition mask holding member 20 included in a mask unit 1 of the present embodiment, the view schematically illustrating a configuration of the vapor deposition mask holding member 20. (b) of FIG. 8 is a plan view of a vapor deposition mask 10 included in the mask unit 1 illustrated in (a) of FIG. 8, the view schematically illustrating a configuration of the vapor deposition mask 10.

The mask unit 1 of the present embodiment is similar in configuration to the mask unit 1 of Embodiment 1 except for (i) the planar shape of a beam portion 22 (in other words, the opening shape of an opening H) of the vapor deposition mask holding member 20 and (ii) the opening shape of openings S of the vapor deposition mask 10. The description below thus deals only with those shapes.

For the present embodiment, (b) of FIG. 8 illustrates an example case of a vapor deposition mask 10 having openings S each in the shape of a slit extending along the Y direction and arranged along the X direction to form a pattern of stripes. It is needless to say that the present embodiment may also be varied as in Variation of Embodiment 1.

<Vapor Deposition Mask Holding Member 20>

The vapor deposition mask holding member 20 of the present embodiment, as illustrated in (a) of FIG. 8, includes a beam portion 22 extending across a central portion of the vapor deposition mask 10, at which central portion the vapor deposition mask 10 is easily bendable, specifically a beam portion 22 extending in a zigzag (in (a) of FIG. 8, in an M shape as an example) across a center line of the vapor deposition mask 10 which center line extends in the middle, in the Y direction, of the vapor deposition mask 10 (that is, the center line extending along the X direction). The present embodiment is, as in Embodiments 1 to 3, arranged such that the beam portion 22 has a uniform width.

The vapor deposition mask holding member 20 of the present embodiment thus has an opening H surrounded by the frame portion 21, the opening H being separated into five openings H31 to H35 by the beam portion 22. The openings H31 to H35, which are separated from one another by the beam portion 22, combine to total a constant opening length along the Y direction at any location along the X direction in a plan view. In other words, the openings H31 to H35 combine to total a constant opening length on any straight line extending along the Y direction in a plan view.

<Vapor Deposition Mask 10>

The present embodiment is, as in Embodiments 1 to 3, arranged as illustrated in (b) of FIG. 8 such that the openings S are formed in respective portions of the vapor deposition mask 10 which portions do not coincide with the beam portion 22, specifically, the openings S extend, in a plan view, along the Y direction continuously or intermittently in such a pattern as to avoid the beam portion 22.

Thus, the present embodiment is, as in Embodiments 1 to 3, arranged such that (i) the openings S themselves of the vapor deposition mask 10 are so shaped that at any location along the X direction, the total opening length of openings S along the Y direction is constant in a plan view and that (ii) the length of that portion of openings S which overlaps with, among the openings H31 to H35, openings on any straight line extending along the Y direction is constant at any location along the X direction.

The above arrangement allows the present embodiment as well to produce an effect similar to that of Embodiment 1.

The present embodiment is, as described above, arranged to include a beam portion 22 extending in a zigzag across the center line of the vapor deposition mask 10 which center line extends in the middle, in the Y direction, of the vapor deposition mask 10. The beam portion 22 thus directly supports the vapor deposition mask 10 at a plurality of positions in a region of the vapor deposition mask 10 through which region the center line extends and at which region the vapor deposition mask 10 is easily bendable. This arrangement allows the present embodiment to produce the effect of preventing a bend in the vapor deposition mask 10, the effect being greater than those of Embodiments 1 to 3.

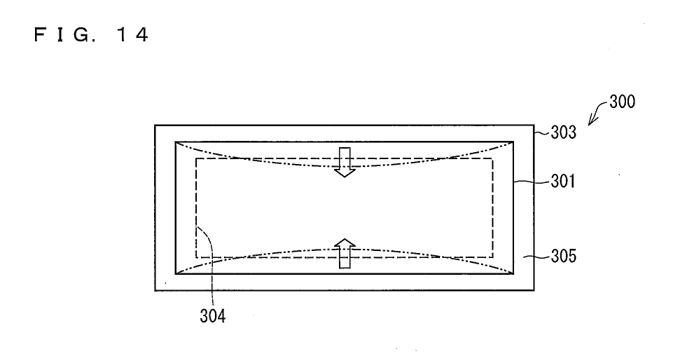

Further, as illustrated in FIG. 14, a vapor deposition mask holding member is, as a vapor deposition mask welded under tension is strongly pulled toward its center, easily deformed at side portions of a frame portion, in particular, at the long-side portions.

In view of the above problem, the present embodiment includes, as illustrated in (a) of FIG. 8, a beam portion 22 connected to the frame portion 21, specifically, a beam portion 22 extending in a zigzag in a region between the long sides of the frame portion 21, at which region the vapor deposition mask holding member 20 is easily deformed. This arrangement can provide the vapor deposition mask holding member 20 with an urge in the direction opposite to the direction of the force by which the frame portion 21 is pulled toward its center as the vapor deposition mask 10 attached to the frame portion 21 pulls it. The above arrangement can effectively prevent the frame portion 21 from being distorted by the force of the pull by the vapor deposition mask 10 welded under tension.

### Embodiment 5

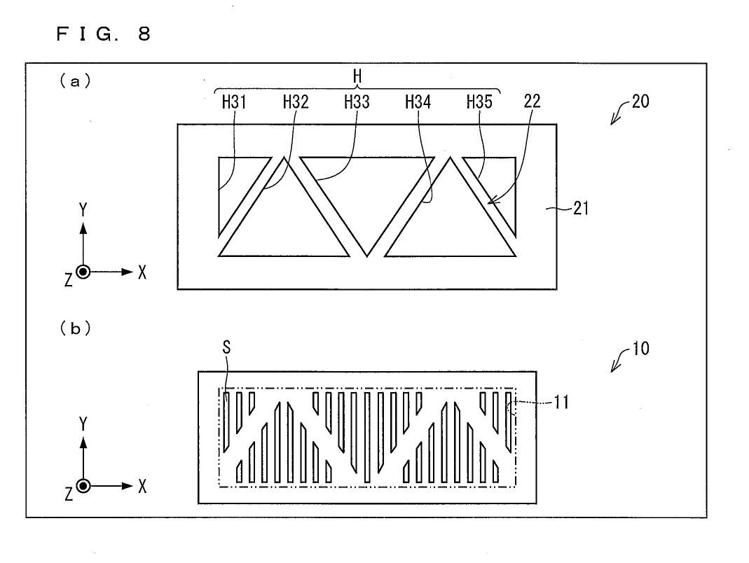

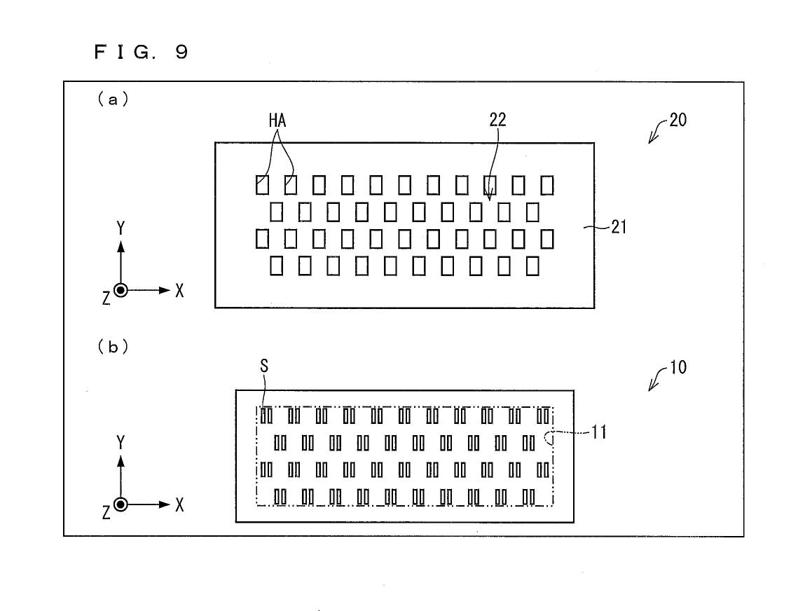

The present embodiment is described below with reference to (a) and (b) of FIG. 9.

The description below mainly deals with how the present embodiment differs from Embodiments 1 to 4. Any constituent element of the present embodiment that is identical in function to a constituent element in Embodiments 1 to 4 is assigned a common reference numeral, and is not described here.

(a) of FIG. 9 is a plan view of a vapor deposition mask holding member 20 included in a mask unit 1 of the present embodiment, the view schematically illustrating a configuration of the vapor deposition mask holding member 20. (b) of FIG. 9 is a plan view of a vapor deposition mask 10 included in the mask unit 1 illustrated in (a) of FIG. 9, the view schematically illustrating a configuration of the vapor deposition mask 10.

The mask unit 1 of the present embodiment is similar in configuration to the mask unit 1 of FIG. 5 of Embodiment 1 except for (i) the planar shape of a beam portion 22 (in other words, the opening shape of an opening H) of the vapor deposition mask holding member 20 and (ii) the opening shape of openings S of the vapor deposition mask 10. The description below thus deals only with those shapes.

<Vapor Deposition Mask Holding Member 20>

The vapor deposition mask holding member 20 of the present embodiment includes, as illustrated in (a) of FIG. 9, a beam portion 22 having, inside a region surrounded by a frame portion 21, a plurality of small-diameter, quadrilateral openings HA in a staggered pattern in a plan view.

The beam portion 22 includes a plate-shaped member having (i) a plurality of openings HA in a staggered pattern and (ii) a non-opening region ranging between edge portions of the frame portion 21 which face each other along the Y direction. The beam portion 22 is, in a plan view, disposed over the entire region surrounded by the frame portion 21.

The openings HA are identical in size to one another. The openings HA are so located that (i) even-numbered rows from either side of the frame portion 21 along either the X direction or the Y direction have openings HA each positioned between openings HA on odd-numbered rows and that (ii) non-opening regions between openings HA are continuous only along directions extending to cross the Y direction (namely, the X direction or an oblique direction between the X direction and the Y direction) and not along the Y direction.

The vapor deposition mask holding member 20 is thus arranged such that openings HA, separated by the beam portion 22, combine to total a constant opening length along the Y direction at any position corresponding to openings HA along the X direction in a plan view (in other words, openings HA combine to total a constant opening length on any straight line extending along the Y direction in a plan view) and that the beam portion (non-opening region), on which vapor deposition cannot be performed, is not continuous along the Y direction.

<Vapor Deposition Mask 10>

The vapor deposition mask 10 has openings S in correspondence with the openings HA (that is, to overlap with the openings HA) in such a pattern as to avoid the beam portion 22 (that is, the non-opening region inside the region surrounded by the frame portion 21) in a plan view as illustrated in (b) of FIG. 9.

The present embodiment is thus arranged as illustrated in (b) of FIG. 9 such that the vapor deposition mask 10 has openings S each in the shape of a slit, the openings S forming groups, each made up of adjacent ones in the X or Y direction of the openings S, that are arranged intermittently along the X direction and the Y direction and that are shifted in position from one another with respect to the X direction and the Y direction.

Thus, the present embodiment is, as in Embodiments 1 to 4, arranged such that (i) the openings S themselves of the vapor deposition mask 10 are so shaped that at any location along the X direction, the total opening length of openings S along the Y direction is constant in a plan view and that (ii) the length of that portion of openings S which overlaps with openings HA on any straight line extending along the Y direction is constant at any location along the X direction.

The above arrangement allows the present embodiment as well to produce an effect similar to that of Embodiments 1 to 4.

The present embodiment is, as described above, arranged such that the mask unit 1 has openings S in correspondence with the openings HA. The vapor deposition mask holding member 20 thus has, over a mask section of the vapor deposition mask 10 (that is, the entire non-opening region of the opening region 11), a beam portion 22 including lateral beams.

With the above arrangement, the vapor deposition mask 10 is directly supported, at that portion of the opening region 11 which is other than the openings S, by the beam portion 22 disposed on the lower surface side of the portion of the opening region 11. This means that the vapor deposition mask 10 is directly held (supported) by the vapor deposition mask holding member 20 at the entire region other than the openings S. The present embodiment can, as a result, produce an effect similar to that of Embodiment 1, and can provide a mask unit 1 including a vapor deposition mask 10 free from a bend.

<Variation of Openings S>

(b) of FIG. 9 illustrates an example case of (i) the vapor deposition mask 10 having openings S in correspondence with the openings HA in such a pattern as to avoid the beam portion 22 in a plan view and (ii) the slit-shaped openings S forming groups, each made up of adjacent ones in the X or Y direction of the openings S, that are arranged intermittently along the X direction and the Y direction and that are shifted in position from one another with respect to the X direction and the Y direction. The present embodiment is, however, not limited to such an arrangement.

As described earlier, the present embodiment simply needs to be arranged, to prevent the amount of vapor deposition from being uneven between openings S adjacent to each other along the X direction, such that at any location along the X direction, the substantial total length of openings of the mask unit 1 is constant along the Y direction in a plan view.

The present embodiment may thus be arranged as in Embodiment 3 such that the openings S overlap with the beam portion 22. The present embodiment is arranged such that openings HA combine to total a constant opening length on any straight line extending along the Y direction at any position corresponding to openings HA along the X direction in a plan view. Thus, the present embodiment can produce its intended effect as long as the respective shapes of the openings S overlapping with the openings HA are identical to one another. This means that openings S overlapping with openings HA adjacent to each other along the Y direction may be continuous with each other.

<Variation of Vapor Deposition Mask Holding Member 20>

The description above deals with a case of the mask unit 1 being similar in configuration to the mask unit 1 of FIG. 5 except for (i) the opening shape of the opening H and (ii) the opening shape of the openings S of the vapor deposition mask 10.

The mask unit 1 may, however, be arranged to include a frame portion 21 and a beam portion 22 integrated with each other.

For instance, the mask unit 1 may be arranged to include a frame portion 21 and a plate-shaped beam portion 22 that have an identical, small thickness and that are integrated with each other, so that the frame portion 21 and the beam portion 22 are not separated from each other by a boundary (that is, to be similar in shape to a single plate).

A typical frame portion 21 is required to be strong enough to withstand the tension of the vapor deposition mask 10, and is thus inevitably thick.

The beam portion 22 (mask supporting section) is, in contrast, merely required to be thick enough to (i) support the vapor deposition mask 10 and (ii) not suffer from a self-weight bend.

A beam portion 22 having a large area, such as the beam portion 22 of the present embodiment, can minimize tension needed for the vapor deposition mask 10, and eliminates the need for a conventional frame rigid enough to withstand the tension. The present embodiment thus allows the frame portion 21 to have a thickness that is as close as possible to that of the beam portion 22. The present embodiment, as a result, allows the vapor deposition mask holding member 20 to be similar in structure to a single plate as described above.

Preparing a vapor deposition mask holding member 20 with a frame portion 21 and a beam portion 22 having the respective thicknesses equal to each other as above merely requires forming openings in a flat plate.

In the above case, the thickness of the vapor deposition mask holding member 20 (that is, that of a plate-shaped member having the openings HA) may, depending on such aspects as the material of the vapor deposition mask holding member 20 and/or the mask size of the vapor deposition mask 10, simply be selected as appropriate so that the vapor deposition mask holding member 20 can stably hold the vapor deposition mask 10 and will not suffer from a self-weight bend. As described above, the thickness of the vapor deposition mask holding member 20 depends on, for example, the mask size of the vapor deposition mask 10, and is approximately 2 mm to 15 mm, for example.

### Embodiment 6

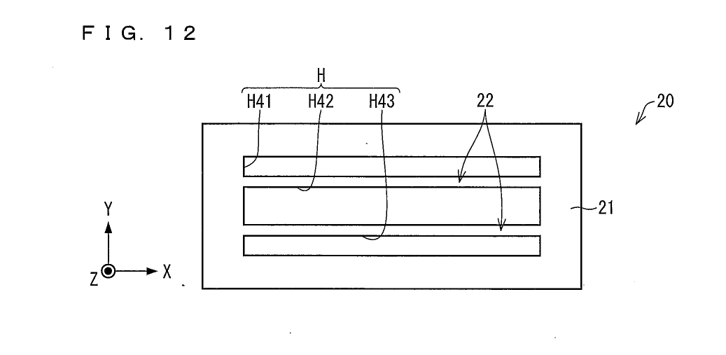

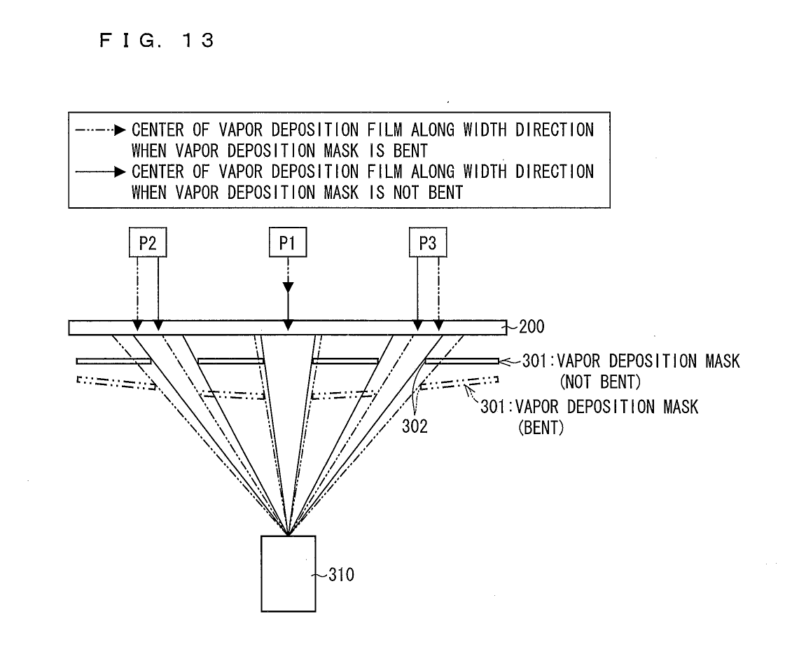

The present embodiment is described below with reference to (a) through (c) of FIG. 10 and FIG. 12.

The description below mainly deals with how the present embodiment differs from Embodiments 1 to 5. Any constituent element of the present embodiment that is identical in function to a constituent element in Embodiments 1 to 5 is assigned a common reference numeral, and is not described here.

(a) through (c) of FIG. 10 are each a diagram schematically illustrating a configuration of a mask unit 1 of the present embodiment. (a) of FIG. 10 is an exploded perspective view of the mask unit 1 of the present embodiment, the view schematically illustrating a configuration of the mask unit 1. (b) of FIG. 10 is a plan view of a vapor deposition mask holding member 20 included in the mask unit 1 illustrated in (a) of FIG. 10, the view schematically illustrating a configuration of the vapor deposition mask holding member 20. (c) of FIG. 10 is a plan view of a vapor deposition mask 10 included in the mask unit 1 illustrated in (a) of FIG. 10, the view schematically illustrating a configuration of the vapor deposition mask 10. For convenience of illustration, (a) of FIG. 10 omits the opening pattern of the vapor deposition mask 10.

The description below deals with how the present embodiment differs from Embodiments 1 to 5.

<Vapor Deposition Mask Holding Member 20>

The vapor deposition mask holding member 20 of the present embodiment includes, as illustrated in (a) and (b) of FIG. 10, (i) a frame portion 21 and (ii) inside a region (opening H) surrounded by the frame portion 21, a frame-shaped beam portion 22 with a three-dimensional framework (three-dimensional structure), the beam portion 22 having island-shaped contact portions 22A for contact with the vapor deposition mask 10.

The beam portion 22 includes longitudinal beams 22B as beam members. The longitudinal beams 22B are oriented in a longitudinal direction (that is, an up-and-down direction or the Z direction), more specifically in an obliquely up-and-down direction, and have vertices at the contact portions 22A for contact with the vapor deposition mask 10. The longitudinal beams 22B are connected directly or indirectly to a lower end 21b of the frame portion 21.

The longitudinal beams 22B, for improved strength, preferably have a radial shape with their vertices at the contact portions 22A. (a) and (b) of FIG. 10 illustrate an example case of the longitudinal beams 22B being erected in the shape of quadrangular pyramids. The longitudinal beams 22B may, however, be erected in the shape of triangular pyramids or of polygonal pyramids with more than four angles.

The longitudinal beams 22B can be made of a metal wire, for example. The longitudinal beams 22B may have a diameter selected as appropriate depending on the number of the contact portions 22A, in other words, on such aspects as the density at which the longitudinal beams 22B are provided and their three-dimensional shape. The diameter of the longitudinal beams 22B is thus not limited to any particular value as long as the longitudinal beams 22B have sufficient strength to hold the vapor deposition mask 10.

The contact portions 22A for contact with the vapor deposition mask 10 are desirably, as illustrated in (a) and (b) of FIG. 10, each a pad portion as an island-shaped member having a buffering function. The pad portions serve to support the vapor deposition mask 10 more stably and to alleviate stress concentration caused by the self-weight of the vapor deposition mask 10 at portions of the vapor deposition mask 10 at which portions the vapor deposition mask 10 is in contact with the contact portions 22A of the beam portion 22. The contact portions 22A are, in other words, preferably each a pad portion having a buffering function.

The pad portions serving as the contact portions 22A may be made of either (i) the same material (for example, a metal material) as that of, for example, the vapor deposition mask 10 or the longitudinal beams 22B or (ii) a material (for example, a heat-resisting rubber or foamed material) different from that of the beam members.

(a) and (b) of FIG. 10 illustrate an example case of the contact portions 22A being each quadrilateral. The shape of the pad portions is, however, not limited to that.

The contact portions 22A are desirably evenly spaced and uniformly spread, for example, disposed to have a fixed density for each unit area. This arrangement allows the contact portions 22A to support the vapor deposition mask 10 more stably and increases the effect of preventing a bend in the vapor deposition mask 10.

To achieve the above desirable arrangement, the example illustrated in (b) of FIG. 10 is so designed that inside the opening H (surrounded by the frame portion 21), (i) there are arranged along the Y direction a plurality of rows (in (b) of FIG. 10, two rows) each formed by a plurality of contact portions 22A arranged on a single straight line extending along the X direction and (ii) contact portions 22A adjacent to each other along the Y direction are arranged on a single straight line extending along the Y direction.

<Vapor Deposition Mask 10>

(c) of FIG. 10 illustrates an example case of a vapor deposition mask 10 having openings S each in the shape of a slit extending along the Y direction and arranged along the X direction to form a pattern of stripes. As mentioned in the description of Embodiment 1, the above opening shape is a mere example, and the present embodiment is not limited by the above arrangement.

The present embodiment is arranged as illustrated in (c) of FIG. 10 such that the openings S is formed in respective portions of the vapor deposition mask 10 which portions do not coincide with the contact portions 22A of the beam portion 22.

The present embodiment is arranged such that the beam portion 22 has contact portions 22A that are not directly connected to the frame portion 21 disposed at the outer edge but in an island shape in a plan view. Thus, the total opening length of the opening H along the Y direction is larger at a location along the X direction at which location contact portions 22A are present in the Y direction than at a location along the X direction at which location contact portions 22A are absent in the Y direction.

The vapor deposition mask 10 illustrated in (c) of FIG. 10 is thus arranged to have (i) belt-shaped non-opening regions each extending along the X direction to, in a plan view, cover contact portions 22A arranged along the X direction and (ii) openings S arranged intermittently along the Y direction in such a pattern as to avoid the beam portion 22 in a plan view.

As a result, the present embodiment is, as in Embodiments 1 to 5, arranged such that (i) the openings S themselves of the vapor deposition mask 10 are so shaped that at any location along the X direction, the total opening length of openings S along the Y direction is constant in a plan view and that (ii) the length of that portion of openings S which overlaps with opening H on any straight line extending along the Y direction is constant at any location along the X direction.

The present embodiment, as illustrated in (a) and (b) of FIG. 10, includes longitudinal beams 22B inside the opening H. Thus, not only the contact portions 22A but also the longitudinal beams 22B overlap with the vapor deposition mask 10 in a plan view.

As described above, however, the longitudinal beams 22B are in a frame shape having a three-dimensional beam structure. This allows vapor deposition particles emitted by a vapor deposition source 70 to pass through the space defined by the longitudinal beams 22B and to be scattered (spread) inside the opening H (surrounded by the frame portion 21).

This means that the longitudinal beams 22B, which overlap with the openings S in a plan view, do not substantially cover the openings S and thus do not hinder uniform vapor deposition.

The above arrangement allows the present embodiment as well to produce an effect similar to that of Embodiment 1.

The present embodiment is arranged such that the beam portion 22 has contact portions 22A that are not directly connected to the frame portion 21 disposed at the outer edge but in an island shape in a plan view. This arrangement allows the region surrounded by the frame portion 21 to have an opening H with a large total area. Thus, the present embodiment can not only directly prevent a bend in the vapor deposition mask 10 but also increase (i) the total opening area of the openings S of the vapor deposition mask 10 and (ii) the degree of freedom for the layout of the opening pattern of the openings S.

As described above, the beam portion 22 (particularly the contact portions 22A thereof) may extend to cross the Y direction intermittently.

The present embodiment includes longitudinal beams 22B that also extend radially to cross the Y direction in a plan view. However, in the case where the beam portion 22 is in a frame shape having a three-dimensional beam structure as described above, the longitudinal beams 22B do not hinder uniform vapor deposition.

The mask unit 1 thus simply needs to be arranged such that the beam portion 22 has parts in contact with the vapor deposition mask 10 (in the present embodiment, the contact regions 22A) that extend to cross the Y direction and that do not bridge the opening H of the frame portion 21 along the Y direction. The mask unit 1 may alternatively be arranged such that the beam portion 22 has beam members in no contact with the vapor deposition mask 10 (for example, at a lower end of the frame portion 21) that are connected to the frame portion 21 in the Y direction.

The present embodiment, as described above, includes a beam portion 22 having a three-dimensional beam structure. This allows the vapor deposition mask holding member 20 to be lightweight.

<Variations of Vapor Deposition Mask 10 and Vapor Deposition Mask Holding Member 20>

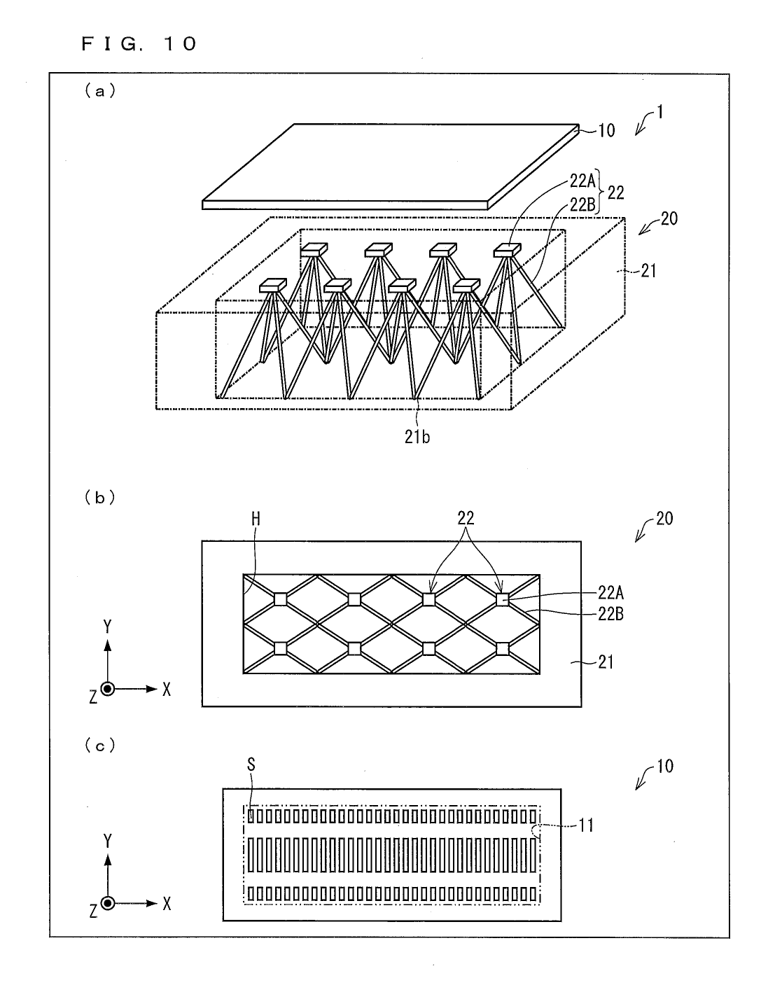

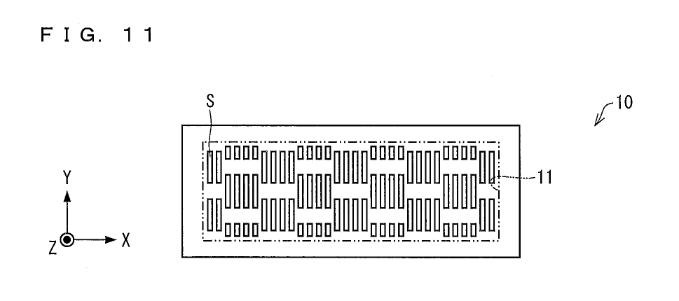

FIG. 11 is a plan view of another vapor deposition mask 10 for use in the mask unit 1 illustrated in (a) of FIG. 10, the view schematically illustrating a configuration of the vapor deposition mask 10.

The vapor deposition mask 10 illustrated in FIG. 11 is, as well as that illustrated in (c) of FIG. 10, arranged to have openings S arranged intermittently along the Y direction in such a pattern as to avoid the beam portion 22 in a plan view. The vapor deposition mask 10 illustrated in FIG. 11 is, however, arranged differently to not only have quadrilateral non-opening regions disposed to, in a plan view, cover contact portions 22A arranged along the X direction, but also have, between the quadrilateral non-opening regions (which cover the contact portions 22A), non-opening regions for the total opening length of openings S along the Y direction to be constant. This allows the openings S of the vapor deposition mask 10 to be arranged such that at any location along the X direction, the total opening length of openings S along the Y direction is constant in a plan view.

Thus, the vapor deposition mask 10 illustrated in FIG. 11 is, as well as that illustrated in (c) of FIG. 10, arranged such that the length of that portion of openings S which overlaps with opening H on any straight line extending along the Y direction is constant at any location along the X direction.

(a) and (b) of FIG. 10 illustrate quadrilateral (for example, square) contact portions 22A, whereas FIG. 11 illustrates quadrilateral (in FIG. 11, rectangular) non-opening regions for covering the contact portions 22A, the non-opening regions being sized to cover the contact portions 22A. The contact portions 22A and the non-opening regions of the vapor deposition mask 10 (which cover the contact portions 22A), however, simply need to be unconnected to the frame portion 21 in a direction parallel to the Y. The contact portions 22A and the non-opening regions of the vapor deposition mask 10 simply need to be so shaped that the contact portions 22A and the non-opening regions are separated by a gap from the frame portion 21 disposed at the outer edge (that is, the vapor deposition mask holding member 20 has, in the Y direction, any opening S uncover by the beam portion 22 for vapor deposition of vapor deposition particles) and that the substantial opening length along the Y direction is constant at any location along the X direction. The contact portions 22A and the non-opening regions of the vapor deposition mask 10 may each be, for example, in the shape of a belt extending along the Y direction.

<Variation of Vapor Deposition Mask Holding Member 20>

FIG. 12 is a plan view of another vapor deposition mask holding member 20 for use in the mask unit 1 of the present embodiment, the view schematically illustrating a configuration of the vapor deposition mask holding member 20.

Embodiments 1 to 4 above each include a beam portion 22 extending in a direction oblique with respect to the Y direction. (a) and (b) of FIG. 10 illustrate an example case of longitudinal beams 22B being provided in a direction oblique with respect to the Y direction. The beam portion 22, however, simply needs not to extend parallel to the Y direction in a region facing the vapor deposition region of the film formation target substrate 200. In the case where, for instance, the mask unit 1 includes a vapor deposition mask 10 illustrated in (c) of FIG. 10, the vapor deposition mask holding member 20 may include, for example, a plate-shaped beam portion 22 extending parallel to the X direction in correspondence with the shape of the non-opening regions of the vapor deposition mask 10 as illustrated in FIG. 12.

FIG. 12 illustrates an example case of the beam portion 22 having two beams extending parallel to each other along the X direction. It is needless to say that (i) the vapor deposition mask holding member 20 may alternatively, depending on the shape of the vapor deposition mask 10, include a beam portion 22 having a single beam extending along the X direction or three or more beams extending along the X direction and that (ii) any of the plurality of beam portions 22 may extend obliquely.

[Recap]

A mask unit of mode 1 of the present invention is a mask unit, including: a vapor deposition mask having an opening; and a vapor deposition mask holding member holding the vapor deposition mask, the vapor deposition mask holding member being partially in contact with a lower surface of the vapor deposition mask, the opening of the vapor deposition mask having, as viewed in a direction perpendicular to a mask surface of the vapor deposition mask, a portion uncovered by the vapor deposition mask holding member, the uncovered portion having, at any location along a first direction, a constant total opening length in a second direction orthogonal to the first direction, the vapor deposition mask holding member having, in correspondence with a portion of the vapor deposition mask which portion is other than an edge portion thereof, a contact portion extending to cross the second direction continuously or intermittently in contact with the lower surface of the vapor deposition mask, the contact portion, in correspondence with the portion of the vapor deposition mask which portion is other than the edge portion thereof, not extending continuously along the second direction from end to end of the vapor deposition mask.

With the above arrangement, as viewed in a direction perpendicular to a mask surface of the vapor deposition mask, the vapor deposition mask holding member has, in correspondence with a portion of the vapor deposition mask which portion is other than an edge portion thereof, a contact portion extending to cross the second direction continuously or intermittently in contact with the lower surface of the vapor deposition mask. This can prevent deformation of the vapor deposition mask holding member such as distortion thereof. Further, since the vapor deposition mask holding member has, in correspondence with a portion of the vapor deposition mask which portion is other than an edge portion thereof, a contact portion extending to cross the second direction continuously or intermittently in contact with the lower surface of the vapor deposition mask, the above arrangement can prevent a bend in the vapor deposition mask such as a self-weight bend therein.

Further, with the above arrangement, (i) the vapor deposition mask holding member has a contact portion for contact with the vapor deposition mask, the contact portion extending to cross the second direction continuously or intermittently, and (ii) the contact portion, in correspondence with the portion of the vapor deposition mask which portion is other than the edge portion thereof, does not extend continuously along the second direction from end to end of the vapor deposition mask. Thus, performing scan vapor deposition with the second direction as the scanning direction allows the contact portion (which is of the vapor deposition mask holding member for contact with the vapor deposition mask) to be not parallel to the scanning direction.

This indicates that even in the case where the vapor deposition mask holding member has the contact portion, using the mask unit to perform scan vapor deposition with the second direction as the scanning direction allows vapor deposition to be performed on a region in which the contact portion is present which vapor deposition is similar to vapor deposition performed on a region in which the contact portion is absent. Thus, using the above mask unit as a mask unit for scan vapor deposition allows vapor deposition to be performed through which no misplacement in vapor deposition arises from a bend in the vapor deposition mask.

The mask unit is further arranged such that the opening of the vapor deposition mask has, as viewed in a direction perpendicular to a mask surface of the vapor deposition mask, a portion uncovered by the beam portion, the uncovered portion having, at any location along a first direction, a constant total opening length in a second direction orthogonal to the first direction. This arrangement prevents the amount of vapor deposition from being uneven between individual openings adjacent to each other along the first direction, and thus allows vapor deposition to be uniformly performed even on a display region covered by the contact portion of the vapor deposition mask holding member for contact with the vapor deposition mask. Thus, with the above arrangement, the contact portion of the vapor deposition mask holding member for contact with the vapor deposition mask (i) does not affect vapor deposition, (ii) can prevent misplacement in vapor deposition arising from a bend in the vapor deposition mask, and (iii) allows uniform vapor deposition to be performed. This makes it possible to provide, for example, an organic EL display device free from color mixture.

A mask unit of mode 2 of the present invention may include the arrangement of mode 1, and be preferably further arranged such that the vapor deposition mask holding member has a frame portion and a beam portion provided in a surrounded region surrounded by the frame portion and connected to the frame portion, the contact portion being part of the beam portion; and the contact portion does not bridge the surrounded region along the second direction but extends to cross the second direction continuously or intermittently.

With the above arrangement, the frame portion is combined with the beam portion. This combination can prevent deformation of the frame portion such as distortion thereof without use of a thick (heavy) frame portion with high rigidity. Further, the beam portion is inside an opening region surrounded by the frame portion and in contact with a lower surface of the vapor deposition mask. This can prevent a bend in the vapor deposition mask such as a self-weight bend therein.

Further, with the above arrangement, the contact portion extends to cross the second direction continuously or intermittently, and does not bridge the surrounded region along the second direction. Thus, performing scan vapor deposition with the second direction as the scanning direction allows the beam portion to be not parallel to the scanning direction.

This indicates that using the mask unit to perform scan vapor deposition with the second direction as the scanning direction allows vapor deposition to be performed on a region in which the beam portion is present which vapor deposition is similar to vapor deposition performed on a region in which the beam portion is absent. Thus, using the above mask unit as a mask unit for scan vapor deposition allows vapor deposition to be performed through which no misplacement in vapor deposition arises from a bend in the vapor deposition mask.

The mask unit is further arranged such that the opening of the vapor deposition mask has, as viewed in a direction perpendicular to a mask surface of the vapor deposition mask, a portion uncovered by the beam portion, the uncovered portion having, at any location along a first direction, a constant total opening length in a second direction orthogonal to the first direction. This arrangement prevents the amount of vapor deposition from being uneven between individual openings adjacent to each other along the first direction, and thus allows vapor deposition to be uniformly performed even on a display region covered by the beam portion. Thus, with the above arrangement, the beam portion (i) does not affect vapor deposition, (ii) can prevent misplacement in vapor deposition arising from a bend in the vapor deposition mask, and (iii) allows uniform vapor deposition to be performed. This, as described above, makes it possible to provide, for example, an organic EL display device free from color mixture.

A mask unit of mode 3 of the present invention may include the arrangement of mode 2, and be preferably further arranged such that the opening of the vapor deposition mask does not coincide with the contact portion; and the opening of the vapor deposition mask has, as viewed in the direction perpendicular to the mask surface of the vapor deposition mask, a portion having, at any location along the first direction, a constant total opening length in the second direction.

With the above arrangement, that portion of openings of the vapor deposition mask which is uncovered by the beam portion has a constant total opening length along the second direction at any location along the first direction regardless of whether, as viewed in the direction perpendicular to the mask surface of the vapor deposition mask, that portion of the opening inside the region of the vapor deposition mask holding member which region is surrounded by the frame portion in which portion the beam portion is absent has a constant total opening distance along the second direction at any position along the first direction.

A mask unit of mode 4 of the present invention may include the arrangement of mode 3, and be preferably further arranged such that the surrounded region has, as viewed in the direction perpendicular to the mask surface of the vapor deposition mask, an opening region in which the beam portion is absent, the opening region having a constant total opening length in the second direction at any location along the first direction.

With the above arrangement, the vapor deposition mask has a non-opening region in such a manner that the opening of the vapor deposition mask (i) does not coincide with that portion of the beam portion which is in contact with the vapor deposition mask but (ii) covers the other portion of the beam portion. This easily allows that portion of openings of the vapor deposition mask which is uncovered by the beam portion to have a constant total opening length along the second direction at any location along the first direction.

A mask unit of mode 5 of the present invention may include the arrangement of any of modes 2 to 4, and be preferably further arranged such that the frame portion is quadrilateral; and the beam portion is on at least one diagonal of the frame portion.

With the above arrangement, the beam portion is on at least one diagonal of the frame portion. The beam portion thus extends across a central portion of the vapor deposition mask at which central portion the vapor deposition mask is easily bendable, and can directly prevent a bend in the vapor deposition mask. The above arrangement further allows the vapor deposition mask to be under reduced tension as compared to conventional techniques when the vapor deposition mask is fixed to the vapor deposition mask holding member. In addition, the above arrangement, in which the beam portion is on a diagonal of the frame portion, allows the beam portion 22 to function as a cross bracing, and thus more strongly prevent deformation of the frame portion. The above arrangement, as a result, eliminates the need for a thick (heavy) frame portion with high rigidity, and allows the frame portion to be thin and lightweight as compared to conventional techniques.

A mask unit of mode 6 of the present invention may include the arrangement of mode 5, and be preferably further arranged such that the beam portion is on two diagonals of the frame portion; and as viewed in the direction perpendicular to the mask surface of the vapor deposition mask, the beam portion has, at an intersection of the two diagonals, a width in the second direction, the width being twice as large as a width of a part of the beam portion in the second direction which part is not at the intersection.

With the above arrangement, the beam portion is on two diagonals of the frame portion. The beam portion thus extends across a central portion of the vapor deposition mask at which central portion the vapor deposition mask is easily bendable, and can directly prevent a bend in the vapor deposition mask. The above arrangement further allows the vapor deposition mask to be under reduced tension as compared to conventional techniques when the vapor deposition mask is fixed to the vapor deposition mask holding member. In addition, the above arrangement also, in which the beam portion is on a diagonal of the frame portion, allows the beam portion 22 to function as a cross bracing, and thus more strongly prevent deformation of the frame portion. The above arrangement, as a result, eliminates the need for a thick (heavy) frame portion with high rigidity, and allows the frame portion to be thin and lightweight as compared to conventional techniques.

With the above arrangement, as viewed in the direction perpendicular to the mask surface of the vapor deposition mask, the beam portion has, at an intersection of the two diagonals, a width in the second direction, the width being twice as large as a width of a part of the beam portion in the second direction which part is not at the intersection. Thus, the surrounded region has an opening region in which the beam portion is absent, the opening region having a constant total opening length in the second direction at any location along the first direction.

A mask unit of mode 7 of the present invention may include the arrangement of mode 2, and be further arranged such that the frame portion is quadrilateral; the beam portion is on two diagonals of the frame portion; and as viewed in the direction perpendicular to the mask surface of the vapor deposition mask, (i) the beam portion has a uniform width, and (ii) so that the opening of the vapor deposition mask has a portion uncovered by the beam portion, the uncovered portion having, at any location along the first direction, a constant total opening length in the second direction, the opening of the vapor deposition mask has, along the first direction, a portion in which an intersection of the two diagonals is present in the second direction, the portion having, in the vapor deposition mask, a length along the second direction which length is smaller than a length of another portion of the surrounded region surrounded by the frame portion.

With the above arrangement as well, the beam portion is on two diagonals of the frame portion. The beam portion thus extends across a central portion of the vapor deposition mask at which central portion the vapor deposition mask is easily bendable, and can directly prevent a bend in the vapor deposition mask. The above arrangement further allows the vapor deposition mask to be under reduced tension as compared to conventional techniques when the vapor deposition mask is fixed to the vapor deposition mask holding member. In addition, the above arrangement, in which the beam portion is on a diagonal of the frame portion, allows the beam portion 22 to function as a cross bracing, and thus more strongly prevent deformation of the frame portion. The above arrangement, as a result, eliminates the need for a thick (heavy) frame portion with high rigidity, and allows the frame portion to be thin and lightweight as compared to conventional techniques.

With the above arrangement, the beam portion is on two diagonals of the frame portion, and as viewed in the direction perpendicular to the mask surface of the vapor deposition mask, the beam portion has a uniform width. The vapor deposition mask holding member is thus arranged such that the total opening length along the second direction is larger at a portion at which the two diagonals intersect than the other portion in the region surrounded by the frame portion.

With the above arrangement, however, the opening of the vapor deposition mask has a portion uncovered by the beam portion, the uncovered portion having, at any location along the first direction, a constant total opening length in the second direction, the opening of the vapor deposition mask has, along the first direction, a portion in which an intersection of the two diagonals is present in the second direction, the portion having, in the vapor deposition mask, a length along the second direction which length is smaller than a length of another portion of the surrounded region surrounded by the frame portion. This arrangement prevents the amount of vapor deposition from being uneven between individual openings adjacent to each other along the first direction, and thus allows vapor deposition to be uniformly performed even on a display region covered by the beam portion.

A mask unit of mode 8 of the present invention may include the arrangement of any of modes 2 to 4, and be preferably further arranged such that the beam portion has a zigzag shape as viewed in the direction perpendicular to the mask surface of the vapor deposition mask.

With the above arrangement, the beam portion has a zigzag shape as viewed in the direction perpendicular to the mask surface of the vapor deposition mask. The beam portion thus extends across a central portion of the vapor deposition mask at which central portion the vapor deposition mask is easily bendable, and can directly prevent a bend in the vapor deposition mask.

Further, the vapor deposition mask holding member is, as the vapor deposition mask under tension applied when the vapor deposition mask is fixed to the vapor deposition mask holding member is strongly pulled toward its center, easily deformed at side portions of the frame portion.

With the above arrangement, however, the beam portion has a zigzag shape as viewed in the direction perpendicular to the mask surface of the vapor deposition mask. This can effectively prevent distortion of the frame portion.

A mask unit of mode 9 of the present invention may include the arrangement of any of modes 2 to 4, and be preferably further arranged such that the beam portion is a plate-shaped member having a plurality of opening regions in a staggered pattern; and the beam portion is, as viewed in the direction perpendicular to the mask surface of the vapor deposition mask, provided throughout the surrounded region.

The above arrangement can provide a mask unit including a vapor deposition mask free from a bend.

A mask unit of mode 10 of the present invention may include the arrangement of any of modes 2 to 9, and be preferably further arranged such that the beam portion is thinner than the frame portion.

The above arrangement allows the frame portion to be more lightweight.

A mask unit of mode 11 of the present invention may include the arrangement of mode 1, and be further arranged such that the vapor deposition mask holding member is a plate-shaped member having a plurality of opening regions in a staggered pattern.

The above arrangement also can provide a mask unit including a vapor deposition mask free from a bend.

A mask unit of mode 12 of the present invention may include the arrangement of mode 2 or 3, and be preferably further arranged such that the contact portion of the beam portion, which contact portion is in contact with the vapor deposition mask, has an island shape as viewed in the direction perpendicular to the mask surface of the vapor deposition mask; and the beam portion has a three-dimensional frame of which a vertex corresponds to the contact portion in contact with the vapor deposition mask.

A mask unit of mode 13 of the present invention may include the arrangement of mode 12, and be preferably further arranged such that the beam portion includes longitudinal beams provided in a radial pattern of which a vertex corresponds to the contact portion in contact with the vapor deposition mask.

With each of the above arrangements, the contact portion of the beam portion for contact with the vapor deposition mask is not directly connected to the frame portion disposed at the outer edge but in an island shape as viewed in the direction perpendicular to the mask surface of the vapor deposition mask. This arrangement allows the region surrounded by the frame portion to have an opening with a large total area. Thus, the above arrangement can not only directly prevent a bend in the vapor deposition mask but also increase (i) the total opening area of the openings of the vapor deposition mask and (ii) the degree of freedom for the layout of the opening pattern of the openings.

The beam portion has a frame shape. The longitudinal beams thus do not hinder uniform vapor deposition.

A mask unit of mode 14 of the present invention may include the arrangement of mode 12 or 13, and be preferably further arranged such that the contact portion of the beam portion, which contact portion is in contact with the vapor deposition mask, is provided with an island-shaped member having a buffering function.

The above arrangement can more stably support the vapor deposition mask and alleviate stress concentration caused by the self-weight of the vapor deposition mask at portions of the vapor deposition mask at which portions the vapor deposition mask is in contact with the beam portion.

A vapor deposition device of mode 15 of the present invention is a vapor deposition device, including: the mask unit of any of modes 1 to 14; a vapor deposition source facing the vapor deposition mask of the mask unit and fixed in position relative to the vapor deposition mask; and a moving mechanism for, in a state in which the vapor deposition mask of the mask unit faces a film formation target substrate, moving a first one of (i) a combination of the mask unit and the vapor deposition source and (ii) the film formation target substrate relative to a second one thereof in a scanning direction identical to the second direction, the vapor deposition mask having a width in the second direction which width is smaller than a width of the film formation target substrate in the second direction, the vapor deposition device, while scanning the film formation target substrate along the second direction, causing the vapor deposition source to emit a vapor deposition particle through the opening of the vapor deposition mask onto the film formation target substrate for vapor deposition.

Conventional vapor deposition methods other than the scan vapor deposition method use a vapor deposition mask having a size substantially equal to that of a film formation target substrate to perform vapor deposition. Such conventional vapor deposition methods cannot use a mask frame having a beam structure because such a mask frame having a beam structure would prevent vapor deposition particles from being vapor-deposited on a region covered by the beam.

Further, if the vapor deposition mask holding member has a beam portion having a grid pattern and connected to the frame portion, even using the scan vapor deposition method would, in that region of the film formation target substrate which overlaps with a region of the vapor deposition mask holding member in which region that portion of the beam portion which extends parallel to the scanning direction is present, prevent vapor deposition particles from passing through the vapor deposition mask and thus from being vapor-deposited on that region of the film formation target substrate.

With the above arrangement, however, using the mask unit to perform scan vapor deposition with the second direction as the scanning direction allows vapor deposition to be performed on a region in which the beam portion is present which vapor deposition is similar to vapor deposition performed on a region in which the beam portion is absent. Thus, using the above mask unit as a mask unit for scan vapor deposition allows, without use of a thick (heavy) frame portion with high rigidity in the vapor deposition mask holding member, vapor deposition to be performed through which no misplacement in vapor deposition arises from a bend in the vapor deposition mask.

The present invention is not limited to the description of the embodiments above, but may be altered in various ways by a skilled person within the scope of the claims. Any embodiment based on a proper combination of technical means disclosed in different embodiments is also encompassed in the technical scope of the present invention.

### INDUSTRIAL APPLICABILITY

The present invention is suitably applicable to (i) a mask unit for use in scan vapor deposition based on a scanning method, which causes vapor deposition to be performed while a film formation target substrate and a combination of the mask unit and a vapor deposition source are moved relative to each other for a scan and (ii) a vapor deposition device that includes the mask unit to form a film in a predetermined pattern.

### REFERENCE SIGNS LIST

1 mask unit
2 vacuum chamber
10 vapor deposition mask
10a long side
10b short side
10c lower surface
11 opening region (opening region of the vapor deposition mask)
20 vapor deposition mask holding member
21 frame portion (edge portion)
21a contact surface
21b lower end
22 beam portion
22a top surface (contact portion)
22A contact portion
22B longitudinal beam
22a top surface
22b beam portion intersection region
50 vapor deposition device
51 vacuum chamber
52 substrate holder
53 substrate moving mechanism (moving mechanism)
54 vapor deposition unit
55 vapor deposition unit moving mechanism (moving mechanism)
70 vapor deposition source
71 emission hole
80 mask unit fixing member
200 film formation target substrate
200a long side
200b short side
201 film formation target surface
H, H1, H2, H11-H14, H21-H24, H31-H35, HA opening (opening region)
S opening
g1, g2 gap

1. (canceled)

2. A mask unit for use in scan vapor deposition, which causes vapor deposition to be performed while a film formation target substrate and a combination of the mask unit and a vapor deposition source are moved relative to each other for a scan, the mask unit comprising:
a vapor deposition mask having an opening; and
a vapor deposition mask holding member holding the vapor deposition mask,
the vapor deposition mask holding member being partially in contact with a lower surface of the vapor deposition mask,
the opening of the vapor deposition mask having, as viewed in a direction perpendicular to a mask surface of the vapor deposition mask, a portion uncovered by the vapor deposition mask holding member, the uncovered portion having, at any location along a first direction which is perpendicular to a scanning direction, a constant total opening length in a second direction which is parallel to the scanning direction and is orthogonal to the first direction,
the vapor deposition mask holding member having, in correspondence with a portion of the vapor deposition mask which portion is other than an edge portion thereof, a contact portion extending to cross the second direction continuously or intermittently in contact with the lower surface of the vapor deposition mask, the contact portion, in correspondence with the portion of the vapor deposition mask which portion is other than the edge portion thereof, not extending continuously along the second direction from end to end of the vapor deposition mask,
the vapor deposition mask holding member having a frame portion and a beam portion provided in a surrounded region surrounded by the frame portion and connected to the frame portion, the contact portion being part of the beam portion; and
the contact portion not bridging the surrounded region along the second direction but extends to cross the second direction continuously or intermittently.

3. The mask unit according to claim 2,
wherein:
the opening of the vapor deposition mask does not coincide with the contact portion; and
the opening of the vapor deposition mask has, as viewed in the direction perpendicular to the mask surface of the vapor deposition mask, a portion having, at any location along the first direction, a constant total opening length in the second direction.

4. The mask unit according to claim 3,
wherein
the surrounded region has, as viewed in the direction perpendicular to the mask surface of the vapor deposition mask, an opening region in which the beam portion is absent, the opening region having a constant total opening length in the second direction at any location along the first direction.

5. The mask unit according to claim 2,
wherein:
the frame portion is quadrilateral; and
the beam portion is on at least one diagonal of the frame portion.

6. The mask unit according to claim 5,
wherein:
the beam portion is on two diagonals of the frame portion; and
as viewed in the direction perpendicular to the mask surface of the vapor deposition mask, the beam portion has, at an intersection of the two diagonals, a width in the second direction, the width being twice as large as a width of a part of the beam portion in the second direction which part is not at the intersection.

7. The mask unit according to claim 2,
wherein:
the frame portion is quadrilateral;
the beam portion is on two diagonals of the frame portion; and
as viewed in the direction perpendicular to the mask surface of the vapor deposition mask, (i) the beam portion has a uniform width, and (ii) so that the opening of the vapor deposition mask has a portion uncovered by the beam portion, the uncovered portion having, at any location along the first direction, a constant total opening length in the second direction, the opening of the vapor deposition mask has, along the first direction, a portion in which an intersection of the two diagonals is present in the second direction, the portion having, in the vapor deposition mask, a length along the second direction which length is smaller than a length of another portion of the surrounded region surrounded by the frame portion.

8. The mask unit according to claim 2,
wherein
the beam portion has a zigzag shape as viewed in the direction perpendicular to the mask surface of the vapor deposition mask.

9. The mask unit according to claim 2,
wherein:
the beam portion is a plate-shaped member having a plurality of opening regions in a staggered pattern; and
the beam portion is, as viewed in the direction perpendicular to the mask surface of the vapor deposition mask, provided throughout the surrounded region.

10. The mask unit according to claim 2,
wherein
the beam portion is thinner than the frame portion.

11. A mask unit for use in scan vapor deposition, which causes vapor deposition to be performed while a film formation target substrate and a combination of the mask unit and a vapor deposition source are moved relative to each other for a scan, the mask unit comprising:
a vapor deposition mask having an opening; and
a vapor deposition mask holding member holding the vapor deposition mask,
the vapor deposition mask holding member being partially in contact with a lower surface of the vapor deposition mask,
the opening of the vapor deposition mask having, as viewed in a direction perpendicular to a mask surface of the vapor deposition mask, a portion uncovered by the vapor deposition mask holding member, the uncovered portion having, at any location along a first direction which is perpendicular to a scanning direction, a constant total opening length in a second direction which is parallel to the scanning direction and is orthogonal to the first direction,
the vapor deposition mask holding member having, in correspondence with a portion of the vapor deposition mask which portion is other than an edge portion thereof, a contact portion extending to cross the second direction continuously or intermittently in contact with the lower surface of the vapor deposition mask, the contact portion, in correspondence with the portion of the vapor deposition mask which portion is other than the edge portion thereof, not extending continuously along the second direction from end to end of the vapor deposition mask,
the vapor deposition mask holding member being a plate-shaped member having a plurality of opening regions in a staggered pattern.

12. The mask unit according to claim 2,
wherein:
the contact portion of the beam portion, which contact portion is in contact with the vapor deposition mask, has an island shape as viewed in the direction perpendicular to the mask surface of the vapor deposition mask; and
the beam portion has a three-dimensional frame of which a vertex corresponds to the contact portion in contact with the vapor deposition mask.

13. The mask unit according to claim 12,
wherein
the beam portion includes longitudinal beams provided in a radial pattern of which a vertex corresponds to the contact portion in contact with the vapor deposition mask.

14. The mask unit according to claim 12,
wherein
the contact portion of the beam portion, which contact portion is in contact with the vapor deposition mask, is provided with an island-shaped member having a buffering function.

15. A vapor deposition device, comprising:
the mask unit according to claim 2;
a vapor deposition source facing the vapor deposition mask of the mask unit and fixed in position relative to the vapor deposition mask; and
a moving mechanism for, in a state in which the vapor deposition mask of the mask unit faces a film formation target substrate, moving a first one of (i) a combination of the mask unit and the vapor deposition source and (ii) the film formation target substrate relative to a second one thereof in a scanning direction identical to the second direction,
the vapor deposition mask having a width in the second direction which width is smaller than a width of the film formation target substrate in the second direction,
the vapor deposition device, while scanning the film formation target substrate along the second direction, causing the vapor deposition source to emit a vapor deposition particle through the opening of the vapor deposition mask onto the film formation target substrate for vapor deposition.

16. A vapor deposition device, comprising:
the mask unit according to claim 11;
a vapor deposition source facing the vapor deposition mask of the mask unit and fixed in position relative to the vapor deposition mask; and
a moving mechanism for, in a state in which the vapor deposition mask of the mask unit faces a film formation target substrate, moving a first one of (i) a combination of the mask unit and the vapor deposition source and (ii) the film formation target substrate relative to a second one thereof in a scanning direction identical to the second direction,
the vapor deposition mask having a width in the second direction which width is smaller than a width of the film formation target substrate in the second direction,
the vapor deposition device, while scanning the film formation target substrate along the second direction, causing the vapor deposition source to emit a vapor deposition particle through the opening of the vapor deposition mask onto the film formation target substrate for vapor deposition.
